(19) United States
(12) Patent Application Publication
(10) Pub. No.: US 2016/0160380 A1
(43) Pub. Date: Jun. 9, 2016

(54) Method for crystal growth in a cell in direct thermal contact with the ambient environment

(71) Applicant: Michael Krautter, Montreal (CA)

(72) Inventor: Michael Krautter, Montreal (CA)

(21) Appl. No.: 14/545,752

(22) Filed: Jun. 15, 2015

Related U.S. Application Data
(63) Continuation-in-part of application No. 12/931,288, filed on Jan. 29, 2011, now abandoned.

(30) Foreign Application Priority Data
Feb. 1, 2010 (CA) 2691554

(51) Int. Cl. C30B 7/08

(52) U.S. Cl. CPC C30B 7/08

(57) ABSTRACT

A crystal growing cell which has computerized temperature control and agitation means to inhibit crystal nucleation. The temperature is controlled semi-actively, i.e., by monitoring the temperature with a thermistor and balancing ambient heat loss with heat added to the system by heating resistors or heating elements. When the chemical is completely dissolved by heating the mixture to a temperature above the saturation temperature, the temperature is lowered. At the saturation temperature the temperature is initially reduced slowly to avoid crystal nucleation. The saturation temperature of the initial solution is selected to be at an intermediate temperature which is high enough that the amount of dissolved material is large enough to produce a large crystal or large crystal clusters, yet not so high that the solubility curve has a large slope and therefore requires a high degree of temperature control to avoid crystal nucleation in the solution.

### RELATED APPLICATIONS

The present application is based on and claims the priority of U.S. non-provisional patent application Ser. No. 12/931,288 filed Jan. 29, 2011 by Michael Krautter for “Device for crystal growth at intermediate temperatures using controlled semi-active cooling,” which is based on and claims the priority of Canadian provisional patent application serial number 2,691,554 entitled “Crystal Growing Device,” by Michael Krautter, filed Feb. 1, 2010, now expired, and is incorporated by reference herein.

### FIELD OF THE INVENTION

The present invention is related to science and education toys and kits, and particularly to crystal growing toys and kits.

### BACKGROUND OF THE INVENTION

The symmetry and elegance of crystals holds a timeless appeal. Mineral crystals have been valued as jewels throughout recorded history, and even common crystals are appreciated for their beauty and used for decoration. Although natural crystals can take millennia to form, crystal growing kits allow people to produce crystals over the course of just days or weeks. Children and adults alike find the process of growing crystals themselves fascinating and thrilling.

An exemplary crystal growing kit is Kristal Educational's “Space Age Crystal Growing Kit, Set #641.” The method taught by this kit is to create a solution using a specified amount of a chemical and a specified amount of water. The water is boiled, mixed with the chemical, and stirred until the chemical is completely dissolved in the water to create a water/chemical solution. Rocks or stones are put at the bottom of the solution, the solution is allowed to cool until it is lukewarm, and then seed crystals are added to the solution. It is suggested that the seed crystals be put on top of the rocks. A lid is put on the container with the solution, and the container is put “in a place where it will not be disturbed by movement.” Visible crystals will start to form in a few hours, and the system should not be “disturbed for three or four days.” It should be noted that the instruction to not disturb or agitate the solution is also repeated elsewhere in the kit's instructions. After three or four days the crystals that have grown may be removed from the solution, or the lid may be taken off the container to allow evaporation, producing further crystal growth.

Because crystal nucleation is not avoided in the process taught by the Kristal Educational's “Space Age Crystal Growing Set,” there is a substantial amount of crystallization in the container other than on the main crystal cluster. The kit therefore suggests the additional steps of taking the excess solution and crystals which formed at the top of the solution or at the base of the main crystal cluster, mixing them together, heating it to boiling and stirring to dissolve all the chemical in the mixture, and pouring the heated mixture over the crystal cluster, and allowing further time for the dissolved chemical to crystalize to further increase the size of the crystal cluster.

Other crystal growing kits currently on the market, including: the Smithsonian “Crystal Growing Set—Series 1,” manufactured for the Smithsonian Institution by Natural Science Industries, Ltd. of West Hempstead, N.Y.; Toys 'R Us “Eduscience Crystal Growing Kit”; “Glowing Crystals” manufactured by Thames & Kosmos of Providence, R.I., United States of America; KOSMOS “Kristalle Zuechten,” manufactured by KOSMOS Verlag of Stuttgart Germany; and “Tree of Knowledge Crystal Wonder Crystal Growing Kit” manufactured by Elenco of Wheeling, Ill., United States of America, use essentially the same procedures as Kristal Educational's “Space Age Crystal Growing Set,” which is the original crystal growing set in the toy market. More particularly, all the crystal growing kits currently on the market teach using the chemicals used with Kristal Educational's “Space Age Crystal Growing Set,” creating a solution using boiling water, and not disturbing the solution during the crystal growth. The chemicals and procedures used in Kristal Educational's “Crystal Growing Set,” were written by Kristal Educational's founder, Heinz Juergen Teige, in 1978 in an article entitled “Kristalle Selber Zuechten,” which was published in conjunction with the 1979 Nuernberg Spielzeug Messe (Nuremberg Toy Show). It should also be noted that none of the prior art crystal growing kits teach controlled cooling, much less slow controlled cooling from the saturation temperature to reduce, inhibit, minimize or prevent crystal nucleation. Furthermore, none of the prior art crystal kits use semi-active cooling by monitoring the temperature and balancing ambient heat loss with computer controlled heating. Furthermore, none of the prior art crystal growing kits use of agitation to reduce, inhibit, prevent or minimize crystal nucleation. None of the prior art crystal growing kits are computer controlled or programmable. None of the prior art crystal growing kits include lighting to signal temperature stages or crystal growth stages or user actions. None of the prior art crystal growing kits take advantage of a saturation temperature at an intermediate point in the solubility curve where a substantial amount of chemical is dissolved so as to produce large crystals, yet the slope of the solubility curve is not so large that overly demanding temperature precision is needed to avoid, prevent, inhibit or minimize crystal nucleation in the solution. None of the prior art crystal growing kits make use of a specialized crystal growing apparatus and/or a specialized crystal growing container. And none of the crystal growing kits use different chemicals but in ratios that provide the same saturation temperature to provide the advantage of simplifying the apparatus and process.

It is therefore an object of the present invention to provide a method and apparatus for rapid crystal growth.

It is furthermore an object of the present invention to provide a method and apparatus for rapid crystal growth and/or for the growth of a large crystal (or crystals) which is reproducible and/or easy and/or safe for young children.

It is another object of the present invention to provide a method and apparatus for a crystal growth which is controlled by software.

It is another object of the present invention to provide a method and apparatus for crystal growth which is programmable.

It is another object of the present invention to provide a method and apparatus for a crystal growth for education purposes.

It is another object of the present invention to provide a method and apparatus for a crystal growth for use by children and/or laymen.

It is another object of the present invention to provide a method and apparatus for crystal growth which promotes crystal growth on a seed crystal while reducing, inhibiting, minimizing, or preventing crystal nucleation in the surrounding liquid.

It is another object of the present invention to provide a method for crystal growth in an apparatus where heat loss to the ambient environment is not easily calculable and/or is a significant factor in the temperature control process.

It is another object of the present invention to provide a method and apparatus for crystal growth which signals temperature stages and/or crystal growth stages and/or user actions with lighting, such as colored and/or flashing lighting.

It is another object of the present invention to provide a method and apparatus for agitation of a solution to produce crystal growth.

It is another object of the present invention to provide a method for crystal growth from a chemical/liquid mixture having a saturation temperature high enough above the freezing temperature of the liquid that a substantial amount of the chemical is dissolved, yet not so close to the boiling temperature that uncertainties in temperature yield large uncertainties in the amount of chemical dissolved.

It is another object of the present invention to provide a method for crystal growth from a chemical/liquid mixture having a saturation temperature high enough above the freezing temperature of the liquid that a substantial amount of the chemical is dissolved, yet with a saturation temperature low enough that the slope of the solubility curve reduces the precision of temperature control required for growth of the seed crystal without producing crystal nucleation in the liquid.

It is another object of the present invention to provide a method and apparatus for crystal growth which provides a user with the choice of utilizing two or more chemicals, particularly where the temperature control process is such that the same saturation temperature is utilized for any of the chosen chemicals.

It is another object of the present invention to increase the apparent size of grown crystals and/or increase the apparent rate of growth by utilizing a transparent growth base.

It is another object of the present invention to provide crystals with improved internal illumination.

It is another object of the present invention to facilitate the growth of large crystals by providing seed crystals of increased size.

It is another object of the present invention to provide seed crystals of increased size, for instance by molding of seed crystals.

Additional objects and advantages of the invention will be set forth in the description which follows, and will be apparent from the description or may be learned from the practice of the invention. The objects and advantages of the invention may be realized and obtained by means of the instrumentalities and combinations particularly pointed out in the claims.

### SUMMARY OF THE PRESENT INVENTION

The present invention is directed to a method for growing a crystal from a solution of a chemical in a container by adding the chemical and a liquid to the container to provide a mixture having a saturation temperature due to the relative amounts of the chemical and liquid used, the saturation temperature being below the boiling temperature of the liquid. The mixture is heated to the saturation temperature to produce a solution of the chemical in the liquid, and a seed crystal is submerged in the solution. The solution is then cooled by monitoring the temperature of the solution and applying heat based on the current temperature to balance ambient heat loss to produce crystal growth on the seed crystal.

The present invention is directed to a method for growing a crystal from a solution of a chemical in a container by adding the chemical and a liquid to the container to provide a mixture having a saturation temperature due to the relative amounts of the chemical and liquid used, the saturation temperature being below the boiling temperature of the liquid. The mixture is agitated to produce a vortex and a seed crystal is situated in the vortex so that it does not contact the mixture. The mixture is heated to the saturation temperature to produce a solution of the chemical in the liquid and the vortex is allowed to collapse so that the solution contacts the seed crystal. The solution is then cooled by monitoring the temperature of the solution and applying heat based on the current temperature to balance ambient heat loss to produce crystal growth on the seed crystal.

The present invention is directed to a method for growing a crystal from a solution of a chemical. The chemical is selected from one of two chemicals. Regardless of which chemical is selected, the amount of the chemical added to the liquid provides a particular saturation temperature. The chemical/liquid mixture is heated to the saturation temperature to produce a solution of the chemical in the liquid, and a seed crystal is submerged in the solution. The solution is then cooled by monitoring the temperature of the solution and applying heat based on the current temperature to balance ambient heat loss to produce crystal growth on the seed crystal.

The present invention is also directed to an apparatus for crystal growth having a chamber for containment of a chemical/liquid mixture, a thermistor for monitoring the temperature of the mixture, a heating element for applying heat to the mixture, and an electronic processor receiving temperature information from the thermistor and controlling the heat applied by the heating element. The processor raises the temperature of the mixture to the saturation temperature to produce a solution, and induces controlled cooling of the solution by applying heating based on the monitored temperature provided by said thermistor to balance ambient heat loss.

The present invention is also directed to an apparatus for mixing contents of a container. The apparatus has a base with a seat for seating the container, and a drive motor which rotates a drive housing having an even number, which is at least four, of permanent magnets equidistant from the rotational center of the drive housing and having alternating polarities. The apparatus also has a stirrer in the container and having the same number of permanent magnets of alternating polarities equidistant from a rotational center of the stirrer which is aligned with the rotational center of the drive housing.

The present invention is also directed to an apparatus for crystal growth having a chamber for containment of a chemical/liquid mixture and a non-soluble transparent growth base located in the chamber. At the saturation temperature of the chemical/liquid mixture, the chemical is completely dissolved in the liquid. The transparent growth base has a surface with crystal-growth nucleation sites, and cooling of the chemical/liquid mixture below the saturation temperature produces crystallization on the transparent growth base.

The present invention is also directed to a method for production of a seed crystal for crystal growth. The seed crystal is produced by melting a crystal growth chemical to produce a molten crystal growth chemical, and pouring the molten crystal growth chemical into a mold.

### BRIEF DESCRIPTION OF THE DRAWINGS

Additional goals and features of the invention will be more readily apparent to those skilled in the art from the following detailed description and appended claims when taken in conjunction with the drawings, in which like reference numbers represent corresponding parts throughout.

FIG. 1A shows the crystal growing apparatus of the present invention with a large crystal cluster grown from the top of the growth chamber.

FIG. 1B shows the crystal growing apparatus of the present invention with a large crystal cluster grown from the bottom of the growth chamber.

FIG. 1C shows the crystal growing apparatus of the present invention with the seed crystal holder located inside the whirlpool/vortex in the liquid/solution created by the stirrer when it is rotating at a very high speed.

FIG. 1D shows the crystal growing apparatus of the present invention with a large seed crystal at the bottom of the growth chamber.

FIG. 1E shows the manufacturing of the large seed crystal depicted in FIG. 1D by pouring the molten crystal-growth chemical into a mold.

FIG. 2A is an exploded view of the crystal growing apparatus of the present invention.

FIG. 2B is a cross-sectional view of the seed holder and the screw cap.

FIG. 3 is a cross-sectional view of the portion of the crystal growing apparatus of the present invention which includes the stirrer, heaters, thermistor, and light-emitting diodes.

FIG. 4 is a cross-sectional view of the portion of the crystal growing apparatus of the present invention which includes the stirrer, heaters, thermistor, and light-emitting diodes.

FIG. 5A is a perspective view of the bottom plug of the crystal growing apparatus of the present invention.

FIG. 5B is a cross-sectional side view of the bottom plug of the crystal growing apparatus of the present invention.

FIG. 5C is a side view of the bottom plug of the crystal growing apparatus of the present invention.

FIG. 5D is a top view of the bottom plug of the crystal growing apparatus of the present invention.

FIG. 6A shows the main menu for the computer controlled interface of the present invention.

FIGS. 6B, 6C, 6D, 6E, 6F, and 6G are a flow chart showing the control process for crystal growth method according to a first preferred embodiment where a seed crystal is inserted into the solution.

FIGS. 6H, 6I, 6J, 6K, 6L, 6M, 6N and 6O are a flow chart showing the control process for crystal growth method according to a second preferred embodiment where a whirlpool prevents the solution from touching the seed crystal during initial stages of the process.

FIG. 7A shows temperature versus time (and lighting versus time) and agitation level versus time for crystal growth method according to the method shown in the flowchart of FIGS. 6B, 6C, 6D, 6E, 6F, and 6G.

FIG. 7B shows temperature versus time (and lighting versus time) and agitation level versus time for crystal growth method according to the method shown in the flowchart of FIGS. 6H, 6I, 6J, 6K, 6L, 6M, 6N and 6O.

FIG. 8 shows the circuitry for the microprocessor's control of the MOSFETs, heaters, stirrer, thermistor, and light-emitting diodes for the crystal growing apparatus of the present invention.

FIG. 9A shows the solubility of ammonium phosphate monobasic (MAP) as a function of temperature.

FIG. 9B shows the solubility of potassium aluminum sulfate, i.e., alum, as a function of temperature.

FIG. 9C shows an exemplary solubility curve which is concave downwards at higher temperatures.

### DETAILED DESCRIPTION OF THE PREFERRED EMBODIMENTS

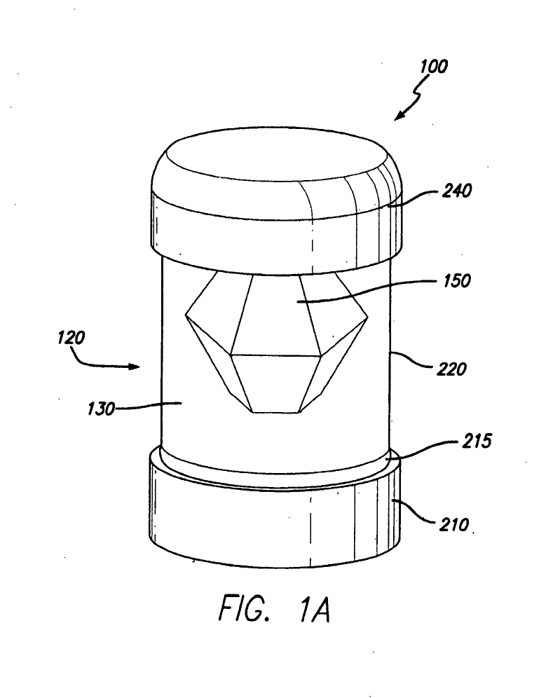

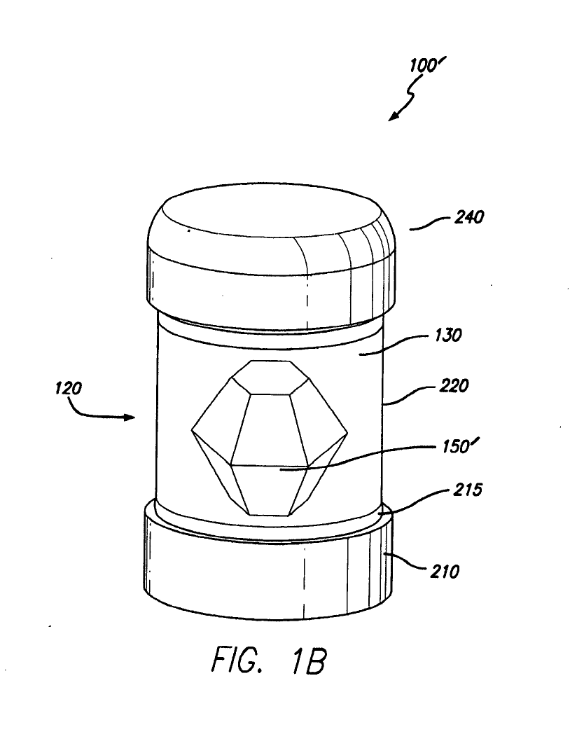

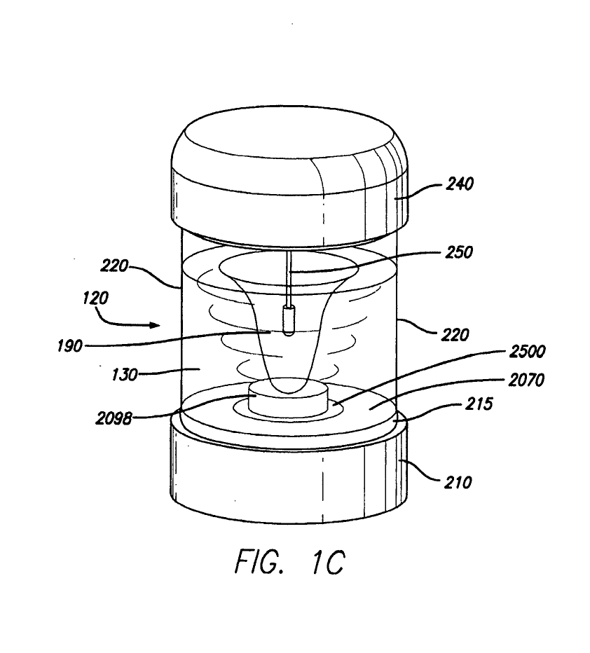

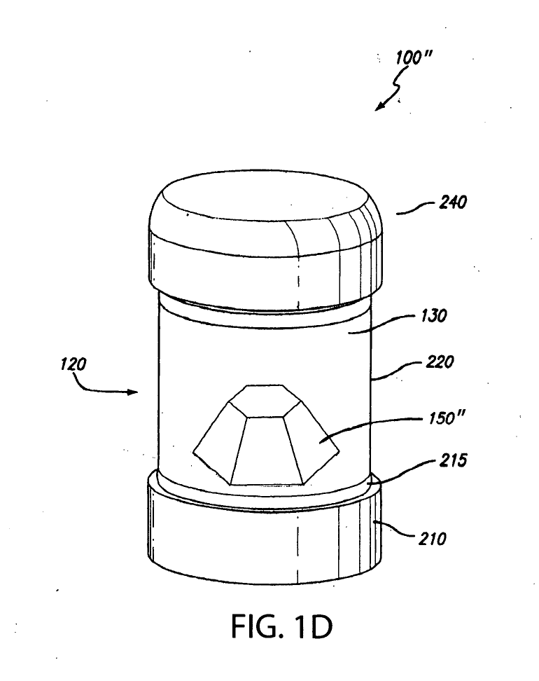

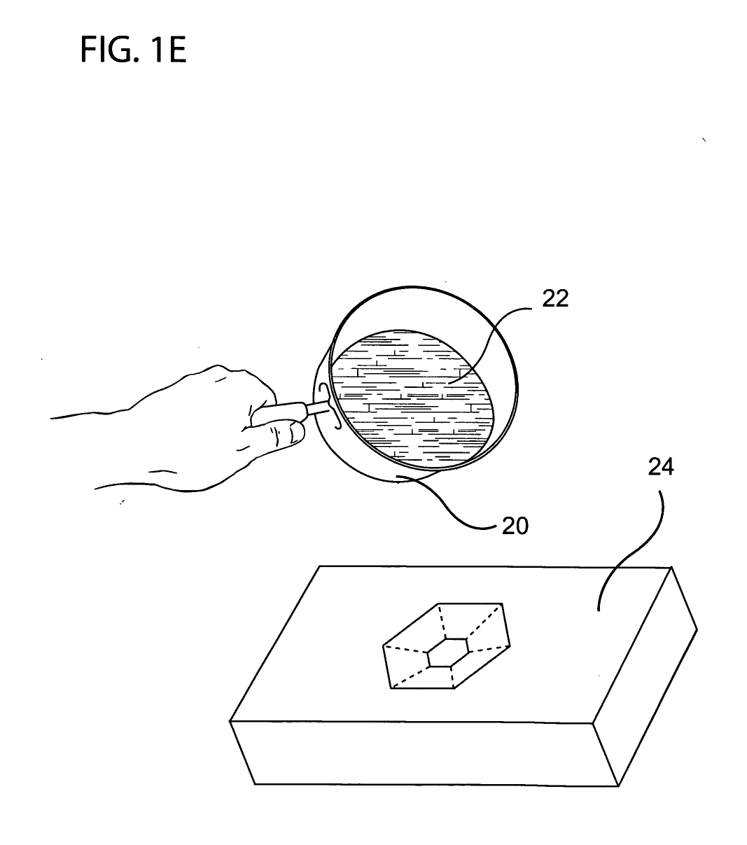

FIG. 1A shows a typical cluster of crystals (150) grown using the method and apparatus (100) for crystal growth according to the present invention. The apparatus (100) has a bottom cap (210), a top cap (240), and transparent, cylindrical, polycarbonate chamber tube (220). Inside the transparent, cylindrical chamber tube (220) and between the bottom cap (210) and the top cap (240) is a sealable chamber (220) which holds a solution or chemical/liquid mixture (130) in which the crystal cluster (150) is grown. At the core of the crystal cluster (150) is a seed crystal holder (not visible in FIG. 1A.) Also visible in FIG. 1A is a polycarbonate base piece (215), about which further details will be provided below.

FIG. 1B shows a typical cluster of crystals (150′) grown using an alternate preferred embodiment of the apparatus (100′) for crystal growth which does not include an agitation mechanism and where the crystal cluster (150′) is grown at the bottom of the chamber (220). The apparatus (100) has a bottom cap (210), a top cap (240), and transparent, cylindrical, polycarbonate chamber tube (220). Inside the transparent, cylindrical chamber tube (220) and between the bottom cap (210) and the top cap (240) is a sealable chamber (220) which holds a chemical/liquid mixture (130) in which the crystal cluster (150′) is grown. Also visible in FIG. 1A is a polycarbonate base piece (215), about which further details will be provided below.

According to an alternate preferred embodiment, crystals are grown on a non-soluble transparent material which acts as a base. For instance, according to this alternate embodiment, the object in the chamber (220) shown in FIG. 1D is a crystal-shaped growth base (150″) made of a transparent non-soluble plastic. Again, the apparatus (100″) has the bottom cap (210), top cap (240), polycarbonate base (215), and transparent, cylindrical, polycarbonate chamber tube (220). Inside the transparent, cylindrical chamber tube (220) and between the bottom cap (210) and the top cap (240) is a sealable chamber (220) which holds a chemical/liquid mixture (130) in which a crystal cluster is grown. Because of the transparency of the growth base (150″), light which enters the growth base (150″) can reach crystals grown on the base, and light which enters crystals grown on the base (150″) can pass through the base (150″) to reach other crystals grown on the base (150″). Therefore, the transparent growth base (150″) provides the advantage over non-transparent growth bases that crystals grown on a transparent growth base (150″) will be better illuminated and so will look more dramatic and beautiful. The plastic cylindrical, polycarbonate chamber tube (220). Inside the transparent, cylindrical chamber tube (220) and between the bottom cap (210) and the top cap (240) is a sealable chamber (220) which holds a solution or chemical/liquid mixture (130) in which the crystal cluster (150) is grown. At the core of the crystal cluster (150) is a seed crystal holder (not visible in FIG. 1A.) Also visible in FIG. 1A is a polycarbonate base piece (215), about which further details will be provided below.

FIG. 1B shows a typical cluster of crystals (150′) grown using an alternate preferred embodiment of the apparatus (100′) for crystal growth which does not include an agitation mechanism and where the crystal cluster (150′) is grown at the bottom of the chamber (220). The apparatus (100) has a bottom cap (210), a top cap (240), and transparent, cylindrical, polycarbonate chamber tube (220). Inside the transparent, cylindrical chamber tube (220) and between the bottom cap (210) and the top cap (240) is a sealable chamber (220) which holds a chemical/liquid mixture (130) in which the crystal cluster (150′) is grown. Also visible in FIG. 1A is a polycarbonate base piece (215), about which further details will be provided below.

According to an alternate preferred embodiment, crystals are grown on a non-soluble transparent material which acts as a base. For instance, according to this alternate embodiment, the object in the chamber (220) shown in FIG. 1D is a crystal-shaped growth base (150″) made of a transparent non-soluble plastic. Again, the apparatus (100″) has the bottom cap (210), top cap (240), polycarbonate base (215), and transparent, cylindrical, polycarbonate chamber tube (220). Inside the transparent, cylindrical chamber tube (220) and between the bottom cap (210) and the top cap (240) is a sealable chamber (220) which holds a chemical/liquid mixture (130) in which a crystal cluster is grown. Because of the transparency of the growth base (150″), light which enters the growth base (150″) can reach crystals grown on the base, and light which enters crystals grown on the base (150″) can pass through the base (150″) to reach other crystals grown on the base (150″). Therefore, the transparent growth base (150″) provides the advantage over non-transparent growth bases that crystals grown on a transparent growth base (150″) will be better illuminated and so will look more dramatic and beautiful. The plastic of the transparent growth base (150″) should be a material whose surface provides crystal growth nucleation sites, and the plastic should be molded to have a surface texture that will provide crystal growth nucleation sites. For instance, silicone is not an acceptable material because its surface does not provide crystal growth nucleation sites. According to the preferred embodiment, the plastic of the transparent base material has a density ρₚ greater than the maximum specific gravity ρₘ of the chemical/liquid mixture (130) throughout the crystal growing process so that the transparent growth base (150′) need not be secured to the chamber (220) and, rather, may be left to rest at the bottom of the chamber (220). For instance, an ammonium phosphate monobasic (MAP)/water solution can have a specific gravity ρₘ as great as 1.4, so the plastic should have a specific gravity ρₚ greater than 1.4. The greater the specific gravity ρₚ of the plastic relative to the specific gravity of the chemical/liquid mixture (130), the greater the flow velocities in the agitated mixture (130) can be without displacing the location of the transparent growth base (150′) at the bottom of the chamber (130). It has been found that a specific gravity ρₚ of at least 10% greater, more preferably 20% greater, and still more preferably 30% greater than the maximum specific gravity ρₘ of the chemical solution is preferred.

According to another alternate preferred embodiment, the crystal cluster is produced by crystal growth on a large seed crystal. As shown in FIG. 1E, according to the present invention the large seed crystal (150″) shown in FIG. 1D is produced by melting the crystal-growth chemical in a crucible (20) to produce the molten state of the chemical, and pouring the molten chemical (22) into a mold (24). Once the molten chemical (22) has cooled to a temperature where it has solidified and can be handled, it can be used as the large seed crystal (150″).

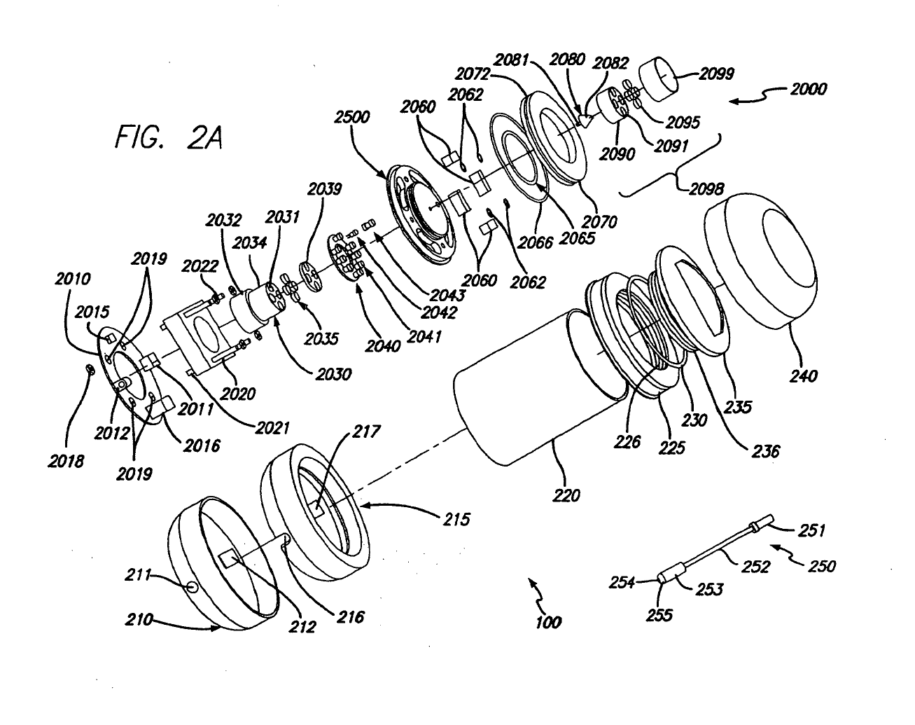

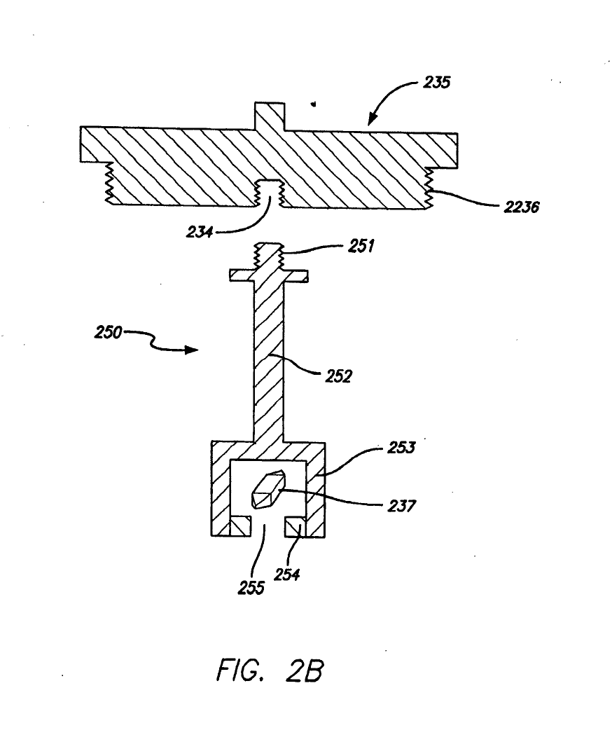

FIG. 2A shows an exploded view of the crystal growing apparatus (100) of the present invention. The bottom cap (210) is made of spun, anodized aluminum and has an inner contour which closely matches the bottom outer contour of the polycarbonate base (215), so that the bottom cap (210) is attachable via pressure fit to the base (215). The bottom cap (210) has two diametrically-opposed apertures (211) and (212), a round aperture (211) and a square aperture (212), the base (215) has two similarly aligned apertures (216) and (217), a round aperture (216) and a square aperture (217), and when the base (215) is seated in the bottom cap (210) the round apertures (211) and (216) and the squares apertures (212) and (217) are aligned to provide two apertures (211)/(216) and (212)/217) for the base (215)/bottom cap (210) assembly. The inner contour of the base (215) has an upper portion which is cylindrical with an inner diameter matching that of the outer diameter of the cylindrical chamber tube (220), so the chamber tube (220) fits into the base (215). The chamber tube (220) is glued into the base (215) to seal the fit. A roughly ring-shaped tube interface (225) made of polycarbonate plastic has an inner, lower contour which is cylindrical and has a diameter which matches that of the outer diameter of the chamber tube (220) so the tube interface (225) mates with the top of the chamber tube (220). The chamber tube (220) is glued into the tube interface (225) to seal the mating. (According to an alternate preferred embodiment, the inner contour of the tube interface (225) and the outer top of the chamber tube (220) are both threaded, and the tube interface (225) is screwed onto the chamber tube (220).) An inside surface of the tube interface (225) is threaded with threads (226) and a screw cap (235) is threaded with threads (236) which mate with the threads (226) of the tube interface (225) so the chamber (220) may be sealed and opened. A silicone or rubber o-ring (230) having an inner diameter slightly larger than the diameter of the threads (236) of the screw cap (235) is situated between the screw cap (235) and the tube interface (225) to improve the sealing. A top cap (240) made of spun, anodized aluminum has an inner contour to provide removable mating via a pressure fit with the screw cap (235).

Shown in cross-section in FIG. 2B, a seed holder (250) has a threaded top portion (251) which mates with a threaded well (234) in the center of the bottom of the screw cap (235). Extending from the threaded top (251) of the seed holder (250) is a shaft (252), and at the bottom end of the shaft (252) is a cylindrical chamber (253). The cylindrical chamber (253) has a removable o-ring (254) having an outer diameter roughly equal to the inner diameter of the chamber (253) at its open end. The o-ring (254) may be removed to allow a seed crystal (237) to be inserted into the chamber (253). Replacing the o-ring (254) then retains the seed crystal (237) in the chamber (253), while the opening (255) at the center of the o-ring (254) allows crystal growth to occur on the seed crystal (237), allowing the seed crystal (237) to grow through/beyond the opening (255) in the o-ring (254)

An exploded view of the stirrer/heating/thermistor/lighting assembly (2000) is also shown in FIG. 2A. The stirrer/heating/thermistor/lighting assembly (2000) has a ring-shaped main printed circuit board (PCB or PCB board) (2010) onto which is mounted a type-B universal serial bus (USB) port (2011), a ¼ inch (0.6 cm) 12 volt direct current power input (2012), an Ardunio Nano V3.0 microprocessor (2015), and control metal-oxide-semiconductor field-effect transistors (MOSFETs) (2016). The downwards projecting rods (2021) pass through holes (not visible in FIG. 2A) in the base (215), and hex nuts (2018) are screwed onto the threaded ends of the downwards projecting rods (2021), thereby securing the PCB board (2010) to the base (215). When the main PCB board (2010) is seated in the base (215), the USB port (2011) and the power input (2012) are aligned with and accessible via the round apertures (211) and (216) and the square apertures (212) and (217) in the end cap (210) and base (215), respectively. The 12 V power input (2012) draws 30 Watts or less, which is sufficient for the process (600), described in detail below, of the present invention for the chamber (220) of the preferred embodiment which has a volume of 697 ml. The LEDs (2041) utilize about 4 watts of power, and heating resistors (2060) utilize about 20 watts. The microprocessor (2015) is powered by the USB port (2011) and utilizes about 5 watts. The power available to the heating resistors (2060) allows the heating resistors (2060) to reach a temperature of about 75° C., which is not high enough to melt the plastics used for the device (100) or the chemicals the device (100) is designed to be used with. The USB port (2011) has a data positive lead, data negative lead, a ground lead, and a Vcc (Vbus) lead. The USB port (2011) allows the apparatus (100) to be interfaced to a laptop or desktop computer (not shown) so that the apparatus (100) may be controlled or directed via the computer, and/or the software on the microprocessor (2015) may be reprogrammed or control parameters in the microprocessor (2015) may be altered from the computer.

Attached to the main PCB board (2010) is a motor (2020). According to the preferred embodiment of the present invention the motor (2020) is a desktop computer cooling fan motor, and in particular according to the present invention the motor is a Fonson model DFDO612H. The housing of the motor (2020) has four downwards-projecting threaded rods (2021) and four upwards-projecting threaded rods (2022). The main PCB board (2010) has four holes (2019) through which the downwards-projecting rods (2021) pass, and the motor (2020) is secured to the main PCB board (2010) by four hex nuts (2018) which are screwed onto the threaded rods (2021). In place of the fan blades (not shown) which are generally driven by a computer fan motor, the motor (2020) drives an agitator drive housing (2030) made of polycarbonate plastic. The agitator drive housing (2030) has a lower cylindrical portion (2032), and an upper cylindrical portion (2034) having a diameter less than that of the lower cylindrical portion (2032). At the top end of the drive housing (2030) are four depressions (2031) into which are seated four permanent magnets (2035). The permanent magnets (2035) are oriented to have alternating polarities, e.g., south, north, south, north, facing upwards. Covering the magnets (2035) is a housing cover (2039) which is attached to the drive housing (2030) via four screws around the perimeter of the cover (2039).

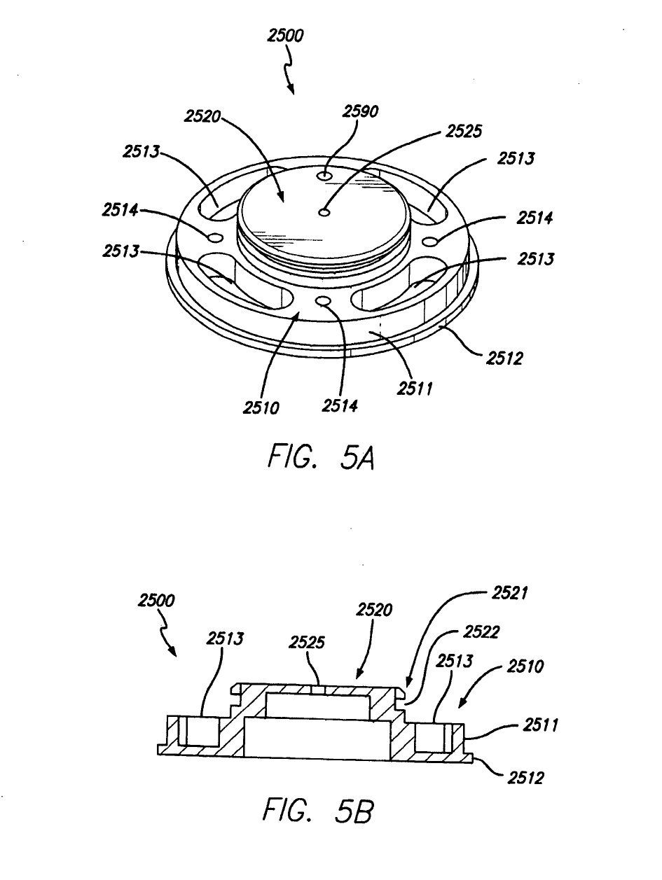

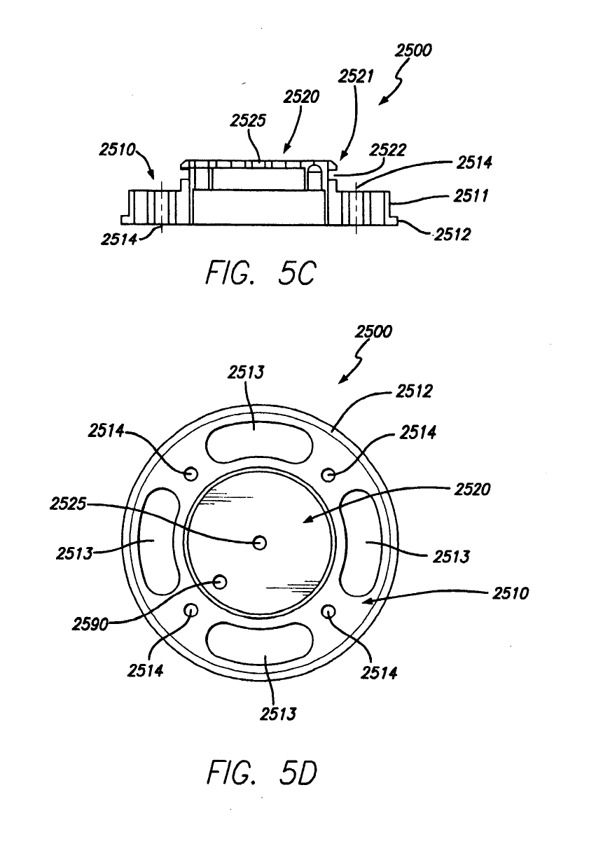

A ring-shaped secondary PCB board (2040) has an inner diameter slightly greater than the outer diameter of the upper cylindrical portion (2034) of the agitator drive housing (2030), and the secondary PCB board (2040) encircles the upper cylindrical portion (2034) of the drive housing (2030). Mounted on the secondary PCB board (2040) are equally-spaced light-emitting diodes (LEDs) (2041) and a thermistor (2042). The thermistor (2042) is covered by a thermistor cap/heat sink (2043) which is pressure-fitted into a hole (2590) (see FIGS. 5A and 5D) in the bottom cap (2500), providing direct contact of the thermistor cap/heat sink (2043) with the solution (130) in the cylinder (220) to facilitate measuring the temperature of the solution (130). The LEDs (2041) have a multiplicity of colors. In the preferred embodiment the LEDs (2041) are blue, yellow, red and green. (According to an alternate preferred embodiment, the LEDs (2041) are ultraviolet, yellow, red and green.)

As shown in FIG. 2A and in more detail in FIGS. 5A, 5B, 5C and 5D, a bottom plug (2500) has an outer portion (2510) and an inner portion (2520). The inner portion (2520) has a top surface which is raised relative to the top surface of the outer portion (2510). The outer side edge (2511) of the outer portion (2510) is cylindrical and has a small lip (2512) along the bottom. The outer side edge (2511), above the lip (2512), has an outside diameter approximately equal to that of the inside diameter of the chamber tube (220), and the chamber tube (220) is mounted on and glued to the bottom plug (2500) to provide a leak-proof seal. According to the preferred embodiment the bottom plug (2500) is made of polycarbonate. (According to an alternate preferred embodiment, the outer edge (2511) of the outer portion (2510) of the bottom plug (2500) is threaded and the inside, bottom portion of the chamber tube (220) is also threaded so the chamber tube (220) can be screwed onto the bottom plug (2500). In addition, according to this alternate embodiment an o-ring (not shown) seated on the lip (2512) further enhances the seal between the bottom plug (2500) and the chamber tube (220).) The top of the outer portion (2510) of the bottom plug (2500) has four equally-spaced arced recesses (2513), and four cylindrical through-bores (2514) between the recesses (2513). A ceramic heating resistor (2060) is situated in each of the four recesses (2513). According to the preferred embodiment, the heating resistors (2060) are 9 ohm, 5 watt ceramic resistors. The four upwards-projecting threaded rods (2022) of the motor (2020) pass through the through-bores (2514) in the bottom plug (2500), and the bottom plug (2500) is secured by four locknuts (2062) to the motor (2020) (as well as the components between the motor (2020) and the bottom plug (2500), which includes: the secondary PCB board (2040), the magnets (2035), and the agitator drive housing (2030)). The outer side wall (2521) of the inner portion (2520) of the bottom plug (2500) has a circumferential groove (2522), and a silicone or rubber o-ring (2065) of roughly the size of the groove (2522) is lodged in the groove (2522).

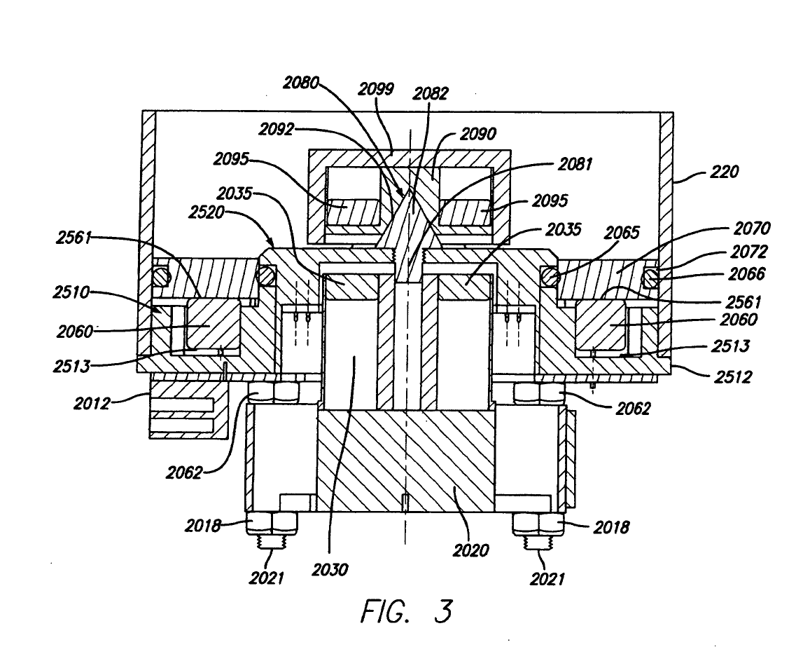

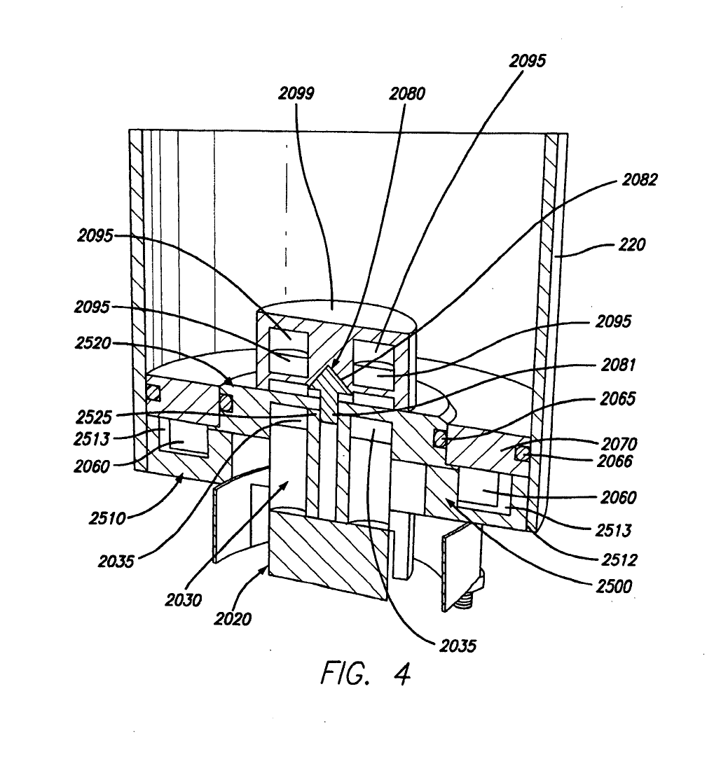

As shown in FIG. 2A, the cross-sectional view of FIG. 3, and the cut-away view of FIG. 4, a flat, ring-shaped, anodized aluminum heating element (2070) is mounted on the upwards-projecting threaded rods (2022) of the motor (2020). The heating resistors (2060) are attached to the heating element (2070) by a heat transfer glue (2561) which facilitates the transfer of heat from the heating resistors (2060) to the heating element (2070). The heating element (2070) makes contact with the liquid (130) in the chamber (220). The rods (2022) screw into threaded wells (2075) in the heating element (2070) which do not go through the heating element (2070) so that the wells (2075) do not allow the possibility of the liquid/solution (130) leaking through the heating element (2070). The heating element (2070) is preferably non-reactive with the chemicals and liquids/solutions used with the apparatus (100). According to the preferred embodiment, the heating element (2070) is anodized aluminum or stainless steel. The inner diameter of the heating element (2070) is slightly larger than that of the outer diameter of the inner portion (2520) of the bottom plug (2500), and the thickness of the heating element (2070) is about equal to the height which the inner portion (2520) of the bottom plug (2500) projects above the top surface of the outer portion (2510) of the bottom plug (2500). The heating element (2070) has a circumferential groove (2072) along the outer side wall, and a silicone or rubber o-ring (2066) of roughly the size of the groove (2072) is lodged in the groove (2072) and extends a little outside the groove (2072) so as to make contact with the chamber tube (220) and provide a waterproof seal between the heating element (2070) and the chamber tube (220). Similarly, the smaller rubber o-ring (2065) extends a little outside the groove (2522) in the bottom plug (2500) so as to make contact with the heating element (2070) and provide a waterproof seal between the heating element (2070) and the bottom plug (2500). Situating the heating element (2070) outside the magnetic stirrer housing (2090) so that it has a large outer diameter provides the advantage that it has a large surface area in contact with the liquid/solution (130) to facilitate heat transfer to the liquid/solution (130).

The thermistor cap (2043) fits snugly in a hole (2590) through the top of the bottom plug (2500). The thermistor cap (2043) is made of anodized aluminum or stainless steel. When liquid (130) is in the chamber (220), the thermistor cap (2043) is in contact with the liquid and shields the thermistor (2042) from the liquid (130) in the chamber (220). Because the thermistor (2042) is located near the heating element (2070), the temperature it (2042) measures may be offset to some degree from the temperature of the bulk liquid/solution (130). According to the preferred embodiment, calibration measurements are taken at the various agitation levels to provide calibration adjustments between the temperature measured by the thermistor (2042) and the actual temperature in the bulk liquid/solution (130).

At the center of the top of the inner portion (2520) of the bottom plug is a threaded well (2525). A stirrer pivot (2080) has a downwards-extending threaded rod (2081) and conical pivot (2082). The threading of the well (2525) and the rod (2081) mate, and the stirrer pivot (2080) is screwed into the threaded well (2525). A magnetic stirrer housing (2090) is substantially cylindrical and at the center of its bottom surface there is a conical indent (2092) with a flare which is slightly larger than the flare of the conical pivot (2081), thereby allowing the stirrer housing (2090) to spin freely on the conical pivot (2082). The upper surface of the stirrer housing (2090) has four indents (2091), and in each of the indents (2091) is a permanent magnet (2095). The permanent magnets (2095) are oriented to have alternating polarities, e.g., north, south, north, south, facing downwards. The four permanent magnets (2095) are magnetically mated with the four permanent magnets (2035) in the agitator drive housing (2030). The four-fold symmetry of the permanent magnets (2095) and the permanent magnets (2035) provides a stable, sustained magnetic mating at high angular velocities. According to the present invention, the number of magnetic poles in the drive housing (2030) and the stirrer (2098) is at least four. A lessor number of magnets cannot provide the same degree of stability in the magnetic engagement for rotation. For instance, a two-fold symmetry in the magnetic mating permits large angular offsets that result in vibrations, slippages and other irregularities and instabilities making it problematic and/or inefficient to reach high angular velocities. A hollow, capped cylindrical stirrer cover (2099) has a cylindrical interior contour which provides a friction fit with the exterior contour of the stirrer housing (2090). The interior of the stirrer cover (2099) is coated with a foil metal shield (not visible) to shield the liquid/solution (130) from the magnetic fields of the permanent magnets (2095) so that the magnetic fields of the permanent magnets (2095) do not interfere with any ions or magnetic particles in the solution (130). (In an alternate embodiment the stirrer cover is a spherical section. The lack of edges of a spherical section provides the advantage of creating less turbulence and higher rotational velocities can be applied without the stirrer cover creating a whirlpool in the liquid/solution (130).) The stirrer housing (2090), permanent magnets (2095), and stirrer cover (2099) forms the stirrer (or rotor) (2098) which is rotatable to agitate the liquid/solution (130). In an alternate preferred embodiment of the present invention the stirrer housing (2090) is made of a material which allows crystal nucleation on its surface. The stirrer housing (2090) must therefore be molded to have a surface texture which allows crystal nucleation on its surface. Preferably the stirrer housing (2090) and the stirrer cover (2099) are made of transparent materials so as to allow illumination of the base, such as by LEDs located below the base, to provide internal illumination of the crystal.

It should be noted that because crystal nucleation can occur throughout the liquid (although, as discussed herein, the method and apparatus of the present invention attempt to minimize the amount and/or likelihood of crystallization other than on the main crystal), the standard construction for a magnetic stirrer where the rotor spins on a cylindrical axle is problematic because of the large surface area of contacting, sliding surfaces. Crystal nucleation between the cylindrical axle and the surrounding cylindrical shaft will increase the sliding friction, possibly to the point where the rotor cannot rotate. The conical pivot (2082) of the present invention provides the advantage of reducing the contact area to essentially a point. Crystals which nucleate at the point of contact between the apex of the conical pivot (2082) and the apex of the conical indent (2092) can move away from the point of contact, and small or even moderate amounts of crystal nucleation do not impede the rotation of the stirrer housing (2090).

The present invention is directed to a means for crystal growth where the heat loss is a significant factor in the temperature control process. It should be noted that heat is lost from the chamber (220) to the ambient environment predominantly through the walls of the polycarbonate chamber tube (220). Less heat is lost through the polycarbonate plug (2500) at the bottom of the chamber (220), and the tube interface (225), screw cap (235), and top cap (210) at the top of the chamber (220). (According to an alternate preferred embodiment, the insulation provided by the chamber tube (220) could be increased by, for instance, substituting a double-walled construction.)

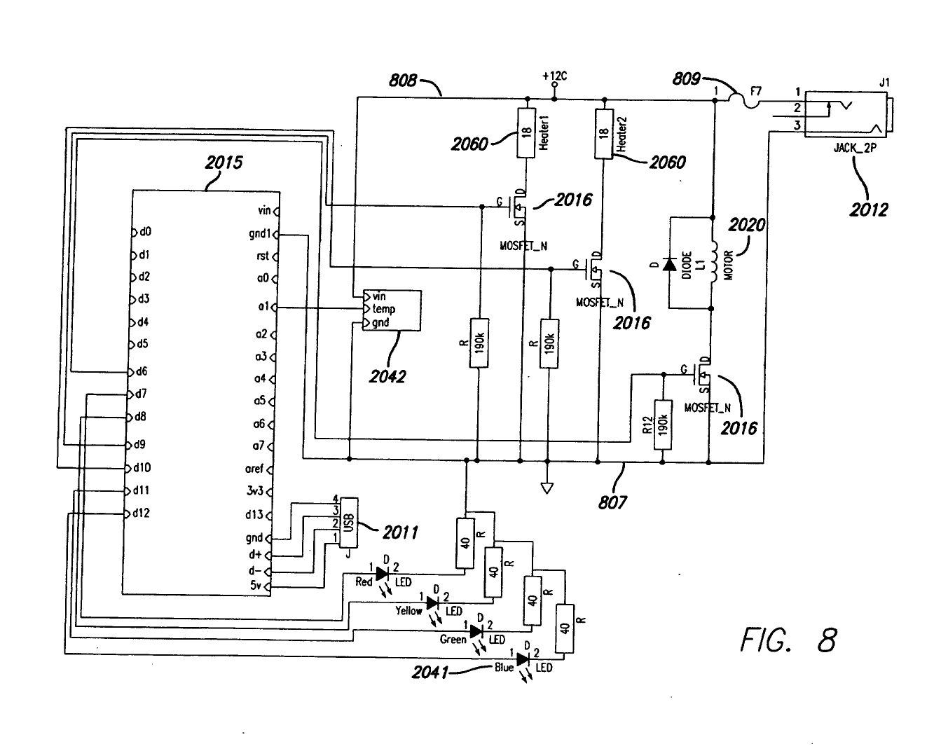

FIG. 8 shows the circuit diagram (800) for the preferred embodiment of the present invention which depicts how the Ardunio Nano V3.0 microprocessor (2015) is interfaced to the USB port (2011), thermistor (2042), MOSFETS (2016), LEDs (2041), motor (2020), and 12 volt power supply (2012). The 12 volt power supply input (2012) powers, via fuse (809) a 12 volt power line (808) and is also connected to a ground line (807). The thermistor (2042) is connected to lead A1 of the microprocessor (2015) and ground (807) and the 12 volt power line (808), allowing the resistance of the thermistor (2042) and therefore the temperature in the chamber (120) to be monitored. USB leads 1 through 4 from the USB port (2011) are connected to leads USB GND, USB D+, USB D− and USB 5V on the microprocessor (2015). Outputs D6, D9, and D10 are connected to the gates of the MOSFETs (2016) to allow control of the MOSFETs (2016) by the microprocessor (2015). The heating resistors (2060) are connected to the drains of the two leftmost MOSFETs (2016) and the 12 volt line (808), and the sources of the two leftmost MOSFETs (2016) are connected to ground (807), allowing a voltage up to roughly the available 12 volts from the power source input (2012) to be applied across the heating resistors (2060). Similarly, the motor (2020) is connected to the drain of the rightmost MOSFET (2016) and the 12 volt power line (808), and the source of the rightmost MOSFET (2016) is connected to ground (807), allowing a voltage up to roughly the available 12 volts from the power source input (2012) to be applied across the motor (2020). The red, yellow, green and blue LEDs (2041) are controlled by outputs D7, D8, D11 and D12, respectively, and are connected in series with 40 ohm resistors to ground (807).

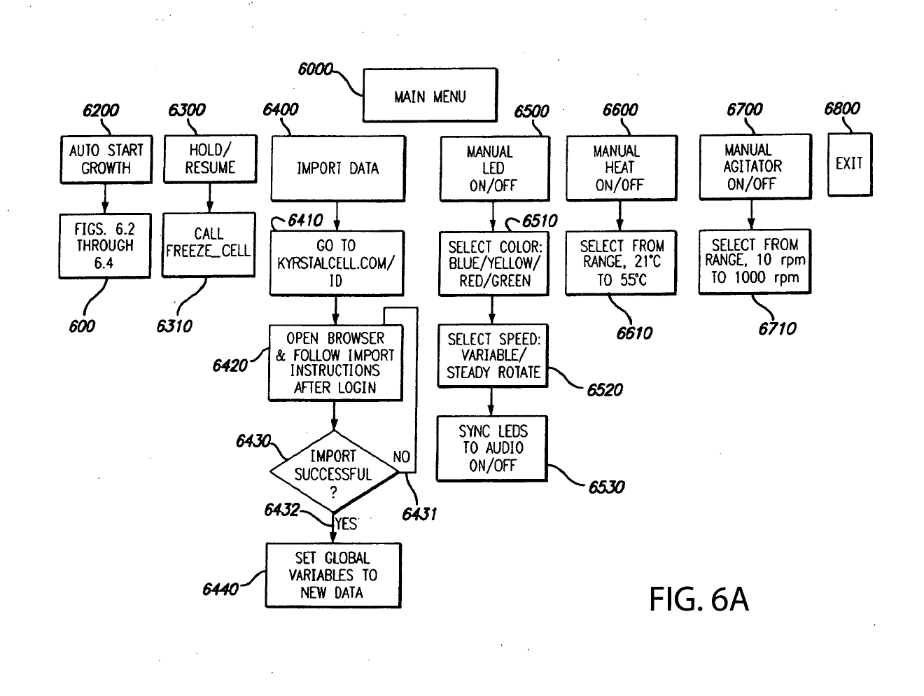

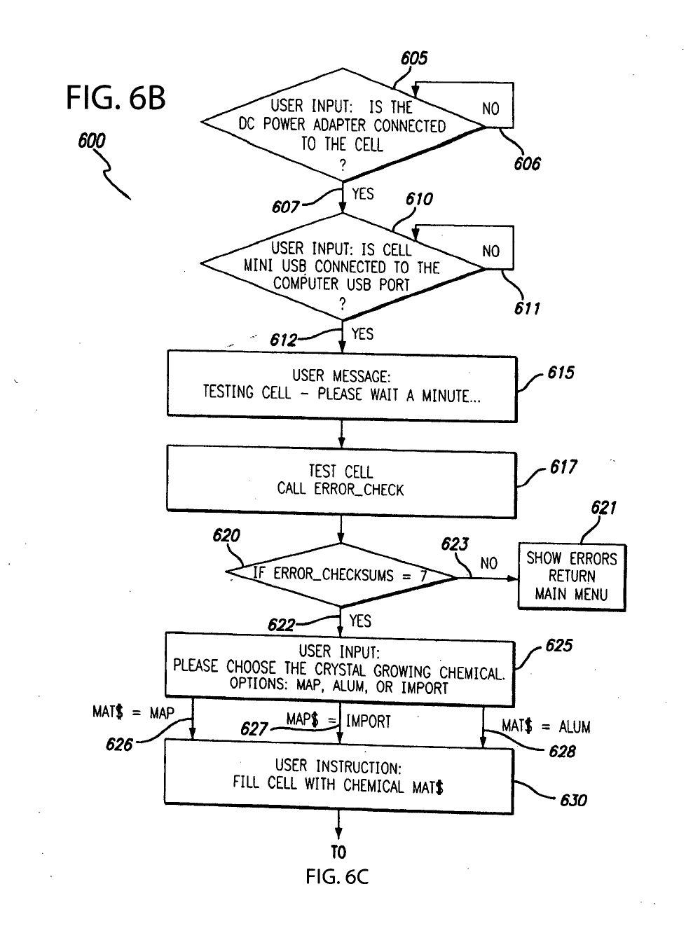

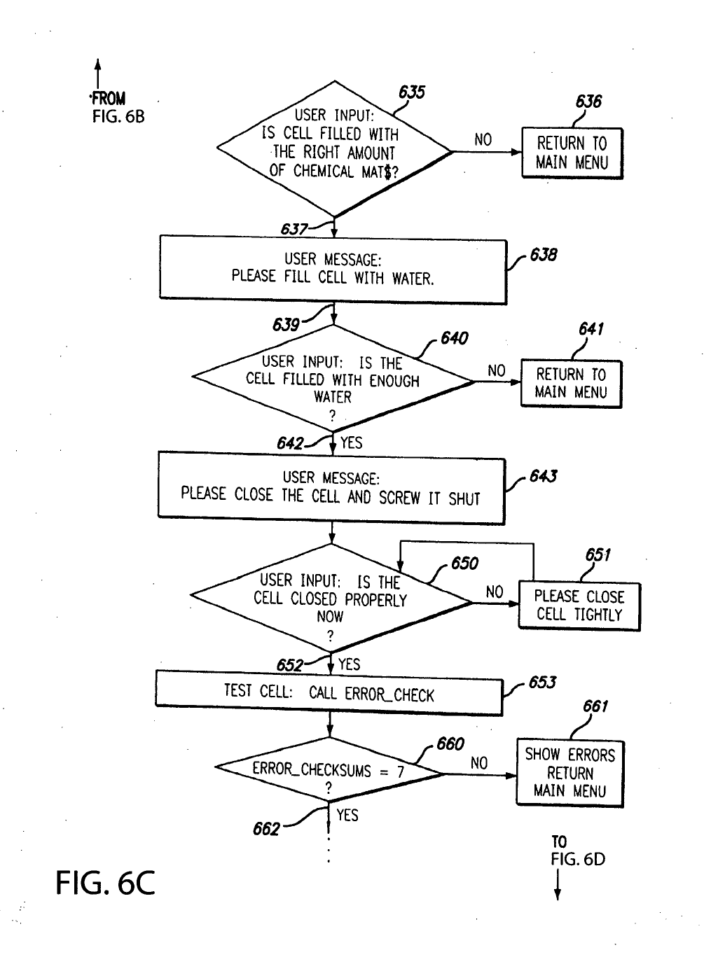

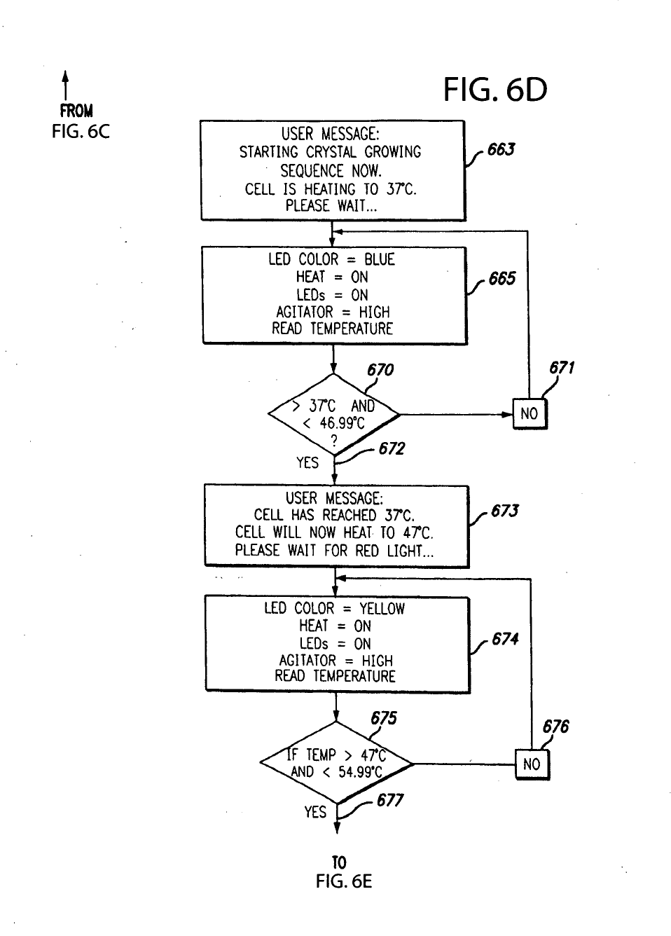

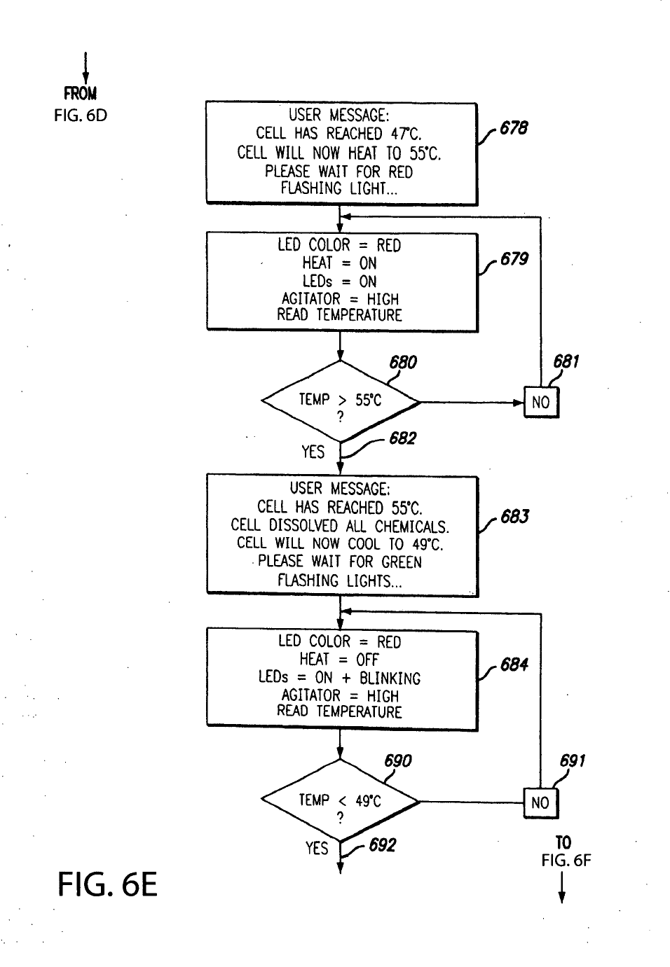

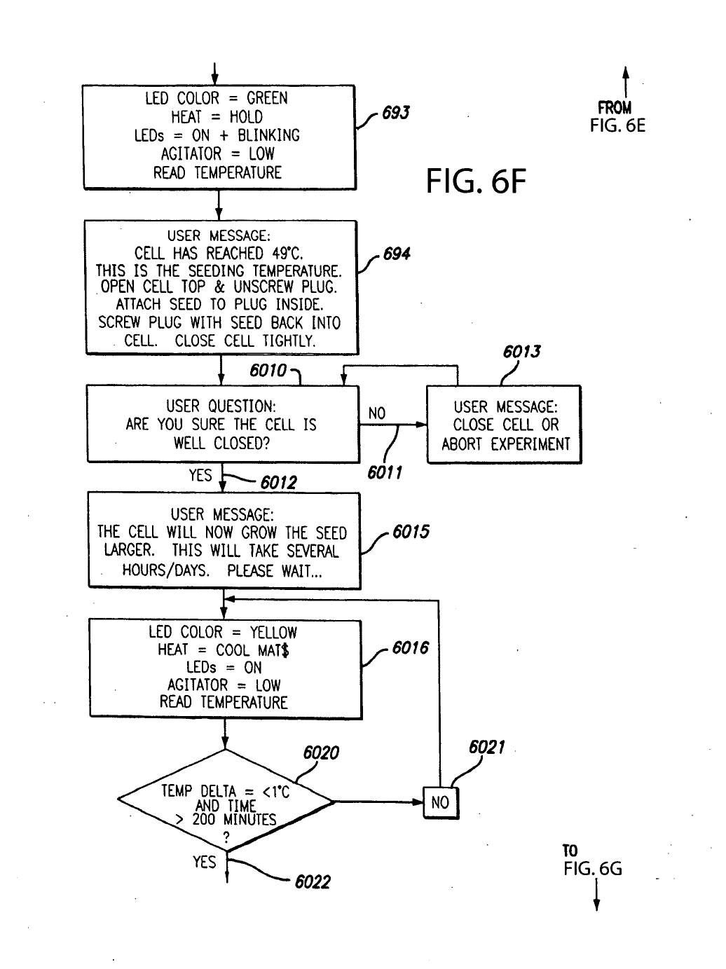

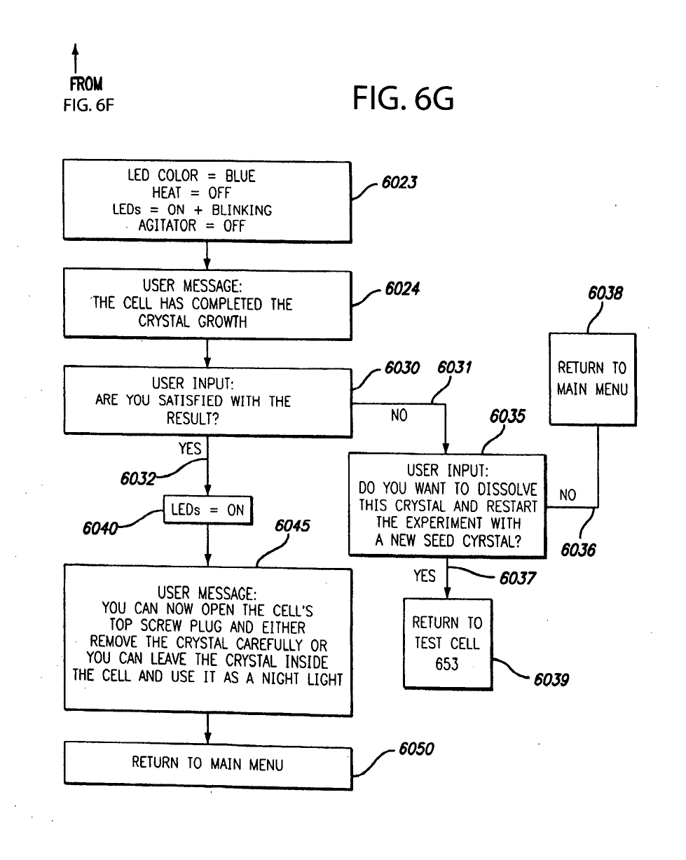

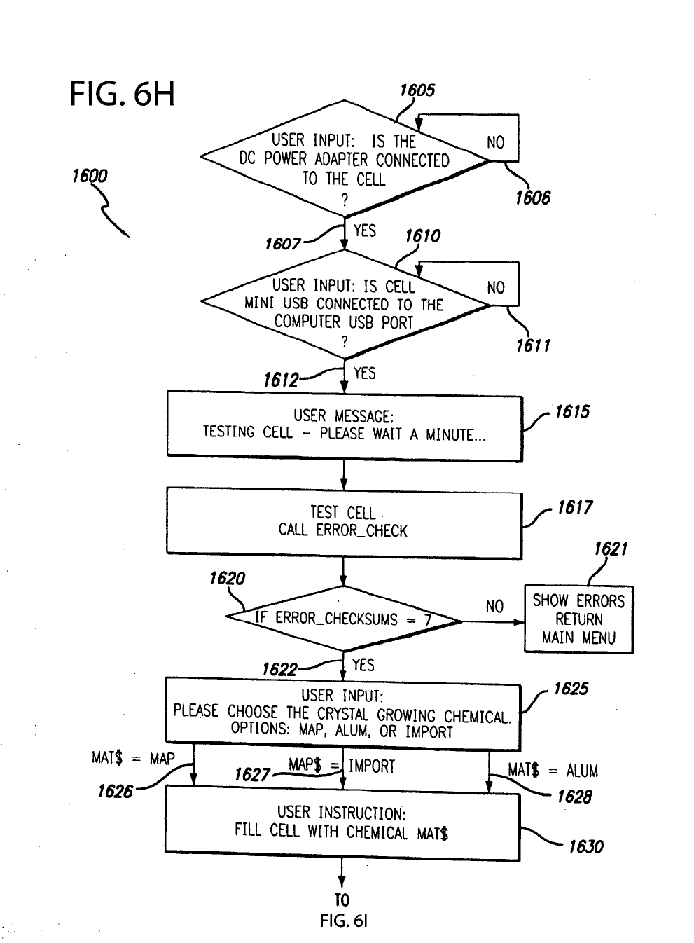

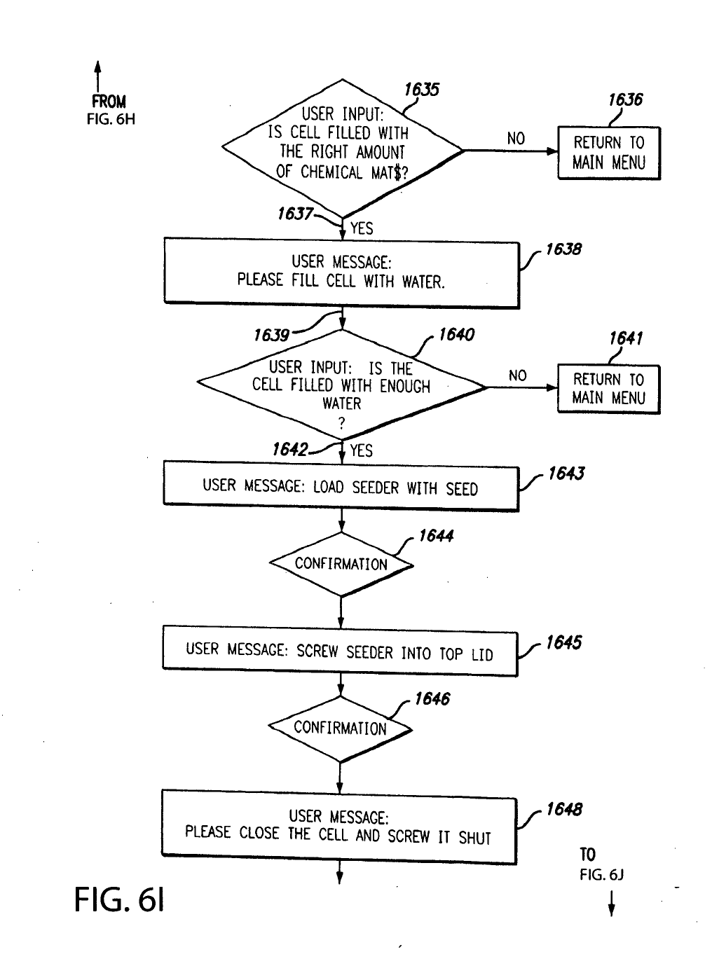

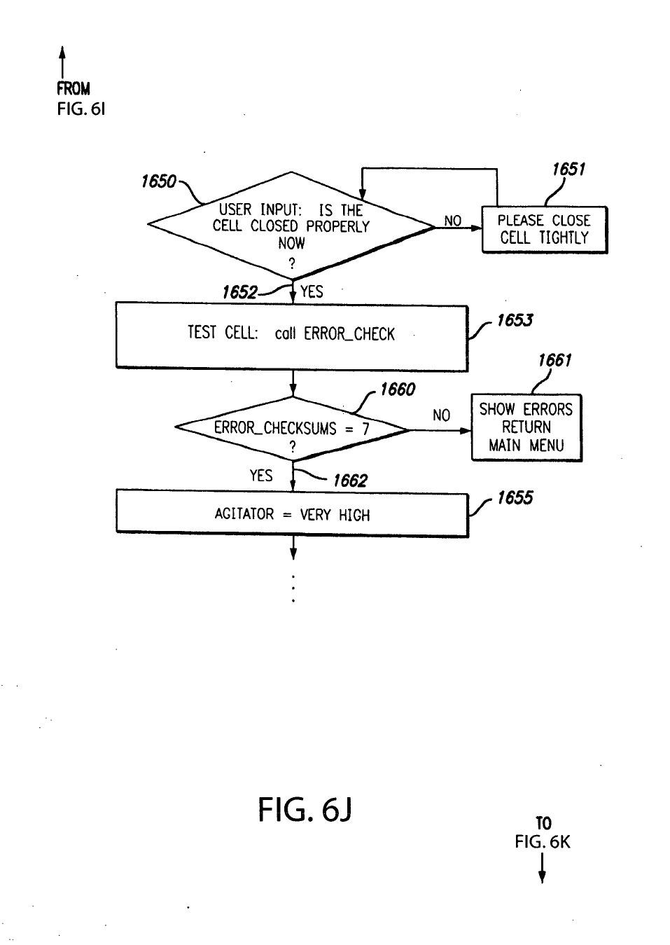

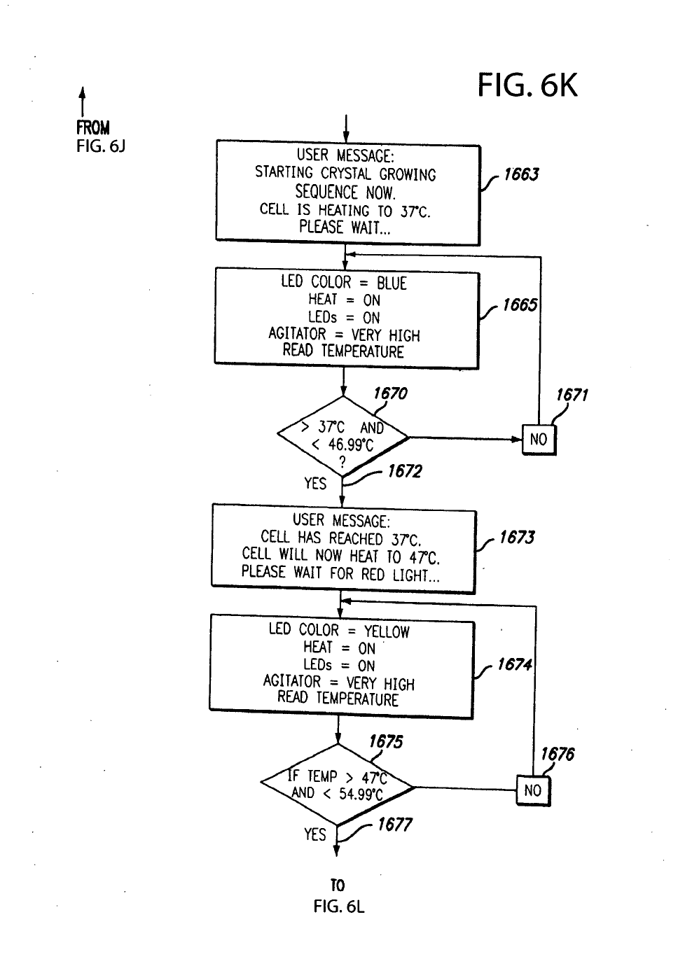

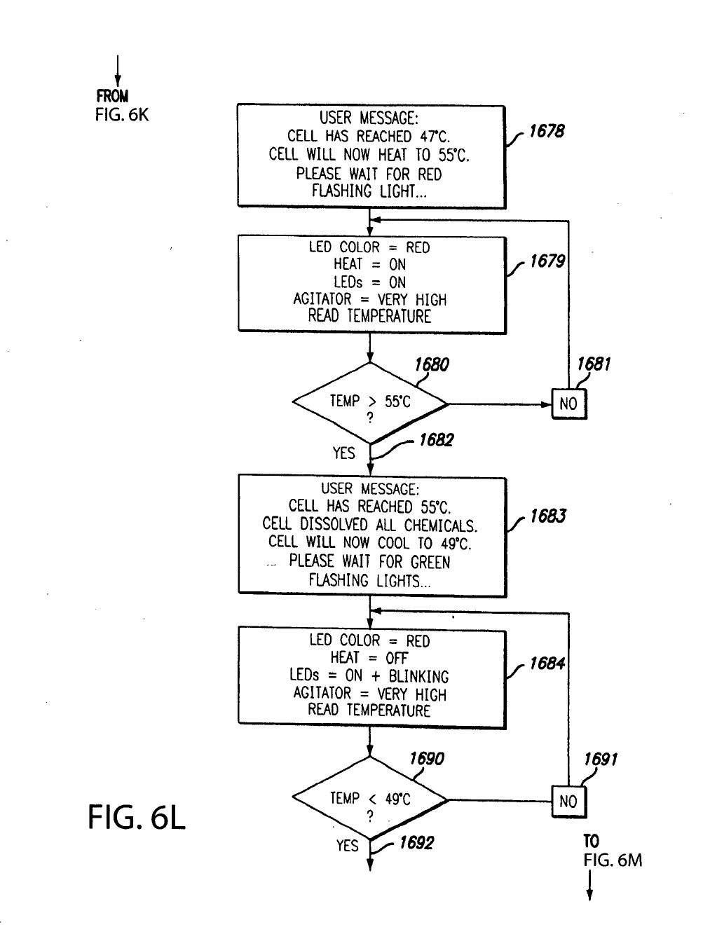

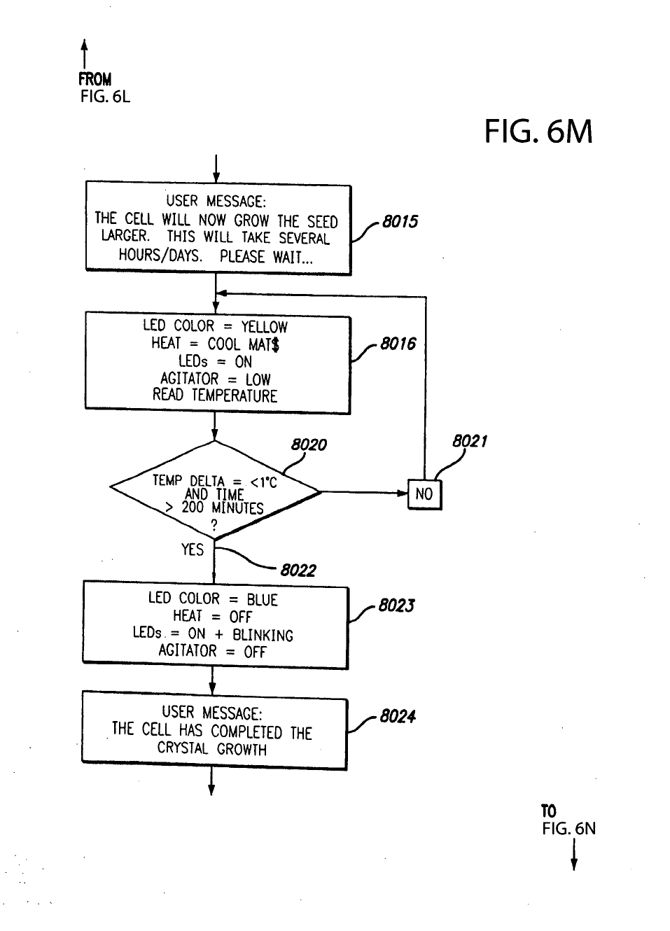

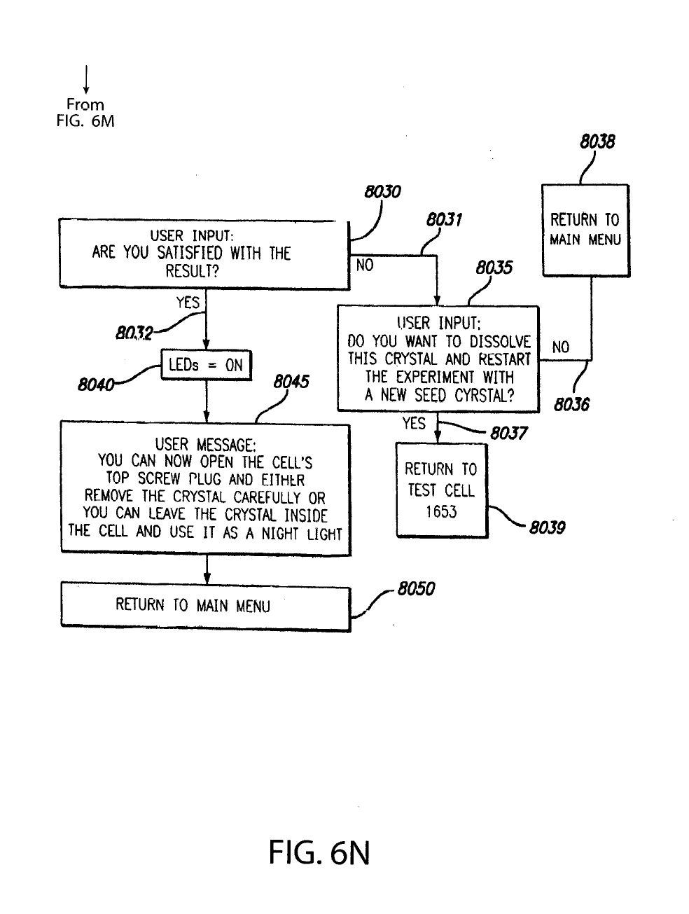

The main menu (6000) for the computer interface of the present invention is shown in FIG. 6A. The user has the options of selecting: starting automatically controlled crystal growth (6200), hold/resume (6300), import data (6400), manual LED control (6500), manual heat control (6600), manual agitator control (6700), or exiting (6800). If hold/resume (6300) is selected, the current states of the LEDs (2041), agitator motor (2020) and heating resistors (2060) are frozen, i.e., maintained. If import data (6400) is chosen, the computer (not shown) calls up (6410) the website www.krystalcell.com/IO, the computer's browser is opened (6420) and the user is instructed to log in and follow the import instructions, the user is queried (6430) as to whether the import has been successful, and if so (6432) the global variables are set (6440) to the imported data. If the import has not (6431) been successful, then control returns to the step (6420) of opening the browser, logging in and following the import instructions. If manual LED control is selected (6500), then the user is allowed to select (6510) the color (blue, yellow, red or green), select (6520) whether the LEDs (2041) flash when on, including being able to select a constant-on state, and allowed to opt (6530) to have flashing of the LEDs (2041) be synced to an audio data signal. If manual heating control (6600) is selected, the user is allowed to select a temperature from the ambient temperature (room temperature is typically 21° C.) to 55° C. to which the chamber (120) is to be heated. If manual agitator control (6700) is selected, the user is allowed to select a rotational velocity from 0 rpm (i.e., no rotation) to 1000 rpm for the agitator motor (2020). The user may also choose to exit (6800) the interface and the device (100) is then turned off.

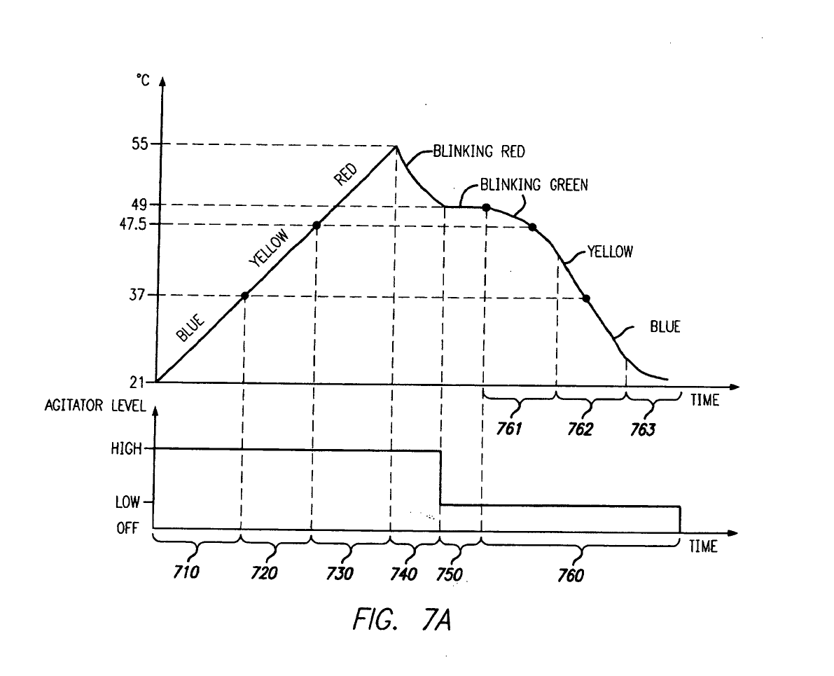

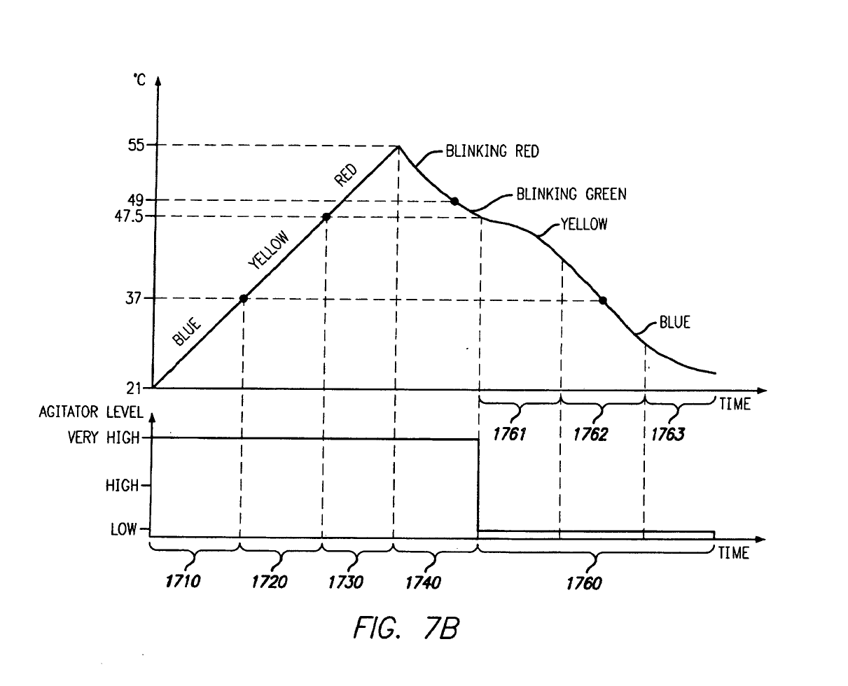

A flowchart of the crystal growth method (600) of the present invention is provided in FIGS. 6B, 6C, 6D, 6E, 6F and 6G and FIG. 7A shows the corresponding temperature and lighting versus time and agitation level versus time. The software interface first displays (605) the message, “User Input: Is the DC power adapter connected to the Krystal Cell?” If the user enters that it is not (606) or does not reply, then the process (600) returns to the display (605) of “User Input: Is the DC power adapter connected to the Krystal Cell?” If the DC power adapter is (607) connected to the apparatus via the power input socket (2012), then the software interface displays (610) the message, “User Input: Is Cell Mini USB connected to the computer USB port?” If the user enters that it is not (611) or does not reply, then the process (600) returns to the display (610) of “User Input: Is Cell Mini USB connected to the computer USB port?” If the apparatus (100) is (612) connected to a computer (not shown) via the mini USB socket (2011), then the software interface displays (615) the message, “User Message: Testing Cell—please wait a minute . . . ”.

The cell is then tested (617) by calling an error check routine, ERROR_CHECK, which checks an error check variable, ERROR_CHECKSUM$. The error check variable ERROR_CHECKSUM$ must have a value of seven if the process (600) is to proceed. The value of ERROR_CHECKSUM$ is initialized with a value of zero, and the value of ERROR_CHECKSUM$ is incremented by unity if a USB cable is connected to the USB port (2011), the value of ERROR_CHECKSUM$ is incremented by unity if there is a signal from the microprocessor (2019) to the computer, the value of ERROR_CHECKSUM$ is incremented by unity if power consumption by the LEDs (2041) is confirmed, the value of ERROR_CHECKSUM$ is incremented by unity if power consumption by the motor (2020) is confirmed, the value of ERROR_CHECKSUM$ is incremented by unity if the thermistor (2042) senses a change in temperature due to heating by the heating resistors (2060), the value of ERROR_CHECKSUM$ is incremented by unity if the user has indicated that the chamber (220) is closed and sealed (or in an alternate embodiment, if contacts at the top of the chamber (220) indicate that the chamber (220) is closed and sealed). In an alternate preferred embodiment, the value of ERROR_CHECKSUM$ is further incremented by unity if the current through the solution resulting from the application of a known voltage indicates a resistance consistent with the presence of the allowed chemicals for use with the device (100) in the proper concentrations, e.g., pure water or an empty container will not provide the proper resistance. If ERROR_CHECKSUM$ does not (621) have a value of seven, then the errors which cause the value of ERROR_CHECKSUM$ to be less than seven are displayed and the process (600) returns to the main menu (6000). However, if ERROR_CHECKSUM$ does (622) have a value of seven, then the message, “User Input: Please choose the crystal growing chemical. Options: MAP, ALUM or IMPORT” is displayed (625). The variable MAT$ is then defined to be either “MAP” (626), “IMPORT” (627) or “ALUM” (628), depending on the input provided by the user.

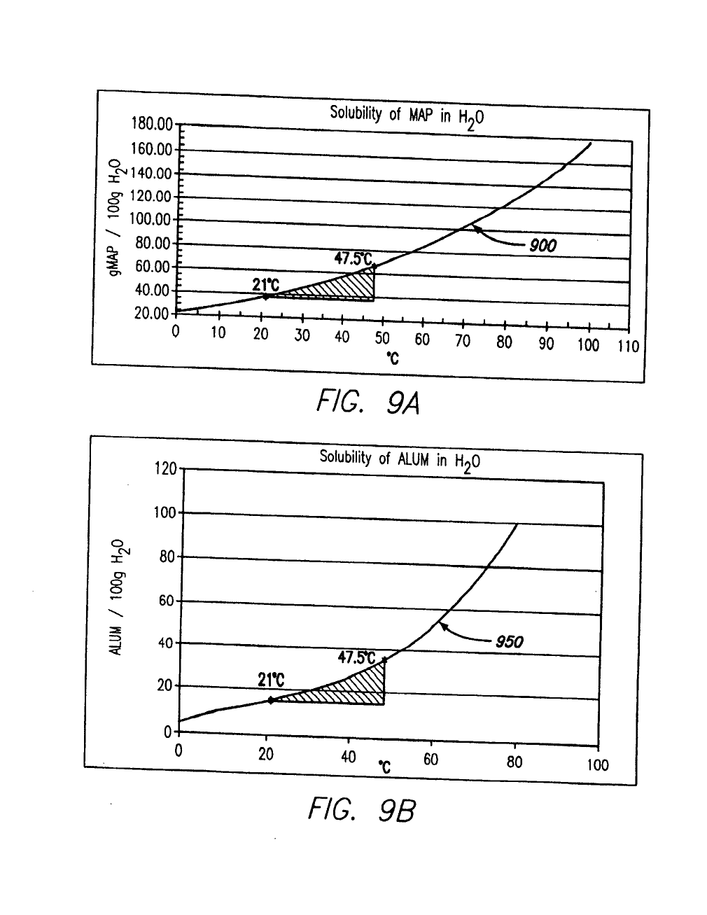

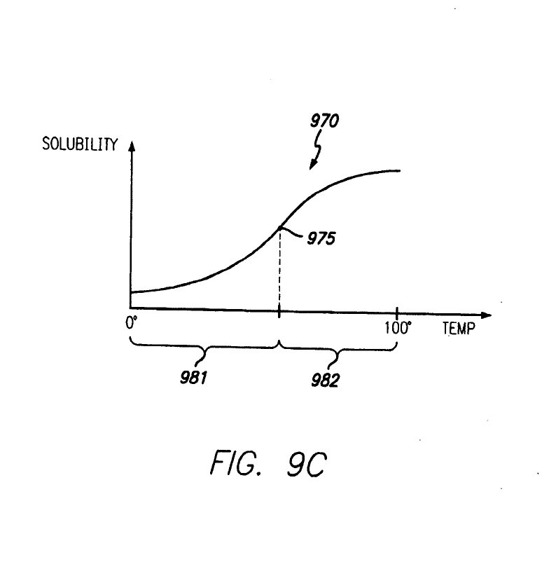

According to the preferred embodiment of the present invention, the crystal growing chemicals to be used with the apparatus include ammonium phosphate monobasic (MAP), which has the chemical formula NH₄H₂PO₄, and potassium aluminum sulfate (alum), which has the chemical formula KAl(SO₄)₂. The solubility of MAP as a function of temperature is shown in FIG. 9A, and the solubility of alum as a function of temperature is shown in FIG. 9B. The IMPORT option (627) also allows the user to update information or to select another chemical for crystallization and import solubility information for use by the device (100). According to an alternate preferred embodiment of the present invention, the chemical used may be phosphorescent or luminescent, or may be doped with a phosphorescent or luminescent additive, and the LEDs (2042) may include ultraviolet LEDs.

The user message, “User instruction: Fill Cell with Chemical MAT$” is then displayed (630), where MAT$ has been defined as MAP or ALUM or the material specified upon importing information. Then the user message, “User Input: Are you done?” is displayed (635). If (636) the user is not done or if the user enters “No,” then the process (600) does not proceed. If (637) the user enters “Yes,” then the user message, “User Message: Please fill Cell with water” is displayed (638) until the user indicates (639) that this has been performed (by clicking on a “next” button, or the like). Then the user message, “User Input: Is the Cell filled with enough water?” is displayed (640). If (641) the user answers “No” or there is no response from the user, the process (600) does not proceed. However, if (642) the user answers “Yes,” the user message, “User Message: Please close the Cell and screw it shut” is displayed (643). Then the user message, “User Input: Is the Cell closed properly now?” is displayed (650). If (651) the user answers “No” or there is no response from the user, the process (600) does not proceed. However, if (652) the user answers “Yes,” a cell testing procedure, ERROR_CHECK, is called (653). As before, ERROR_CHECKSUM$ must have a value of seven if the process (600) is to proceed. If ERROR_CHECKSUM$ does not (661) have a value of seven, then the errors which cause the value of ERROR_CHECKSUM$ to be less than seven are displayed and the process (600) returns to the main menu (6000). However, if ERROR_CHECKSUM$ does (662) have a value of seven, then the message, “User Message: Starting crystal growing sequence now. Cell is heating to 37 degrees C. Please wait . . . ” is displayed (663).

The process (600) now enters preliminary heating control stage (665), which is time region (710) in FIG. 7A. In the preliminary heating control stage (665) the blue LEDs (2041) are lit, the heating resistors (2060) are turned on, the motor (2020) of the agitator is turned on to a high level, and the temperature is monitored by the thermistor (2042). The agitation during this period (710), the period (720) that follows where the temperature is raised to the saturation temperature, and the next period (730) where the temperature is raised above the saturation temperature, increases the speed at which the chemical MAP$ is dissolved. According to the preferred embodiment, when agitation is at the “high” level, the magnetic housing (2090) rotates at 200 to 250 rpm. During the initial period (710) the temperature is monitored (670) as it rises from the ambient temperature (which is typically in the neighborhood of 21° C.) to 37° C. As long as the temperature is not (671) greater than 37° C., the process remains in the preliminary heating control stage (710)/(665).

When (672) the temperature exceeds 37° C., the message “User Message: Cell has reached 37 degrees C. Cell will now heat to 47 degrees C. Please wait . . . ” is displayed (673). The process (600) now enters the intermediate heating control stage (674), which is time region (720) in FIG. 7A. In the intermediate heating control stage (674)/(720) the yellow LEDs (2041) are lit, the heating resistors (2060) are on, the motor (2020) of the agitator is turned on to the high level, and the temperature is monitored by the thermistor (2042). During this period (720) the temperature is monitored (675) as it rises from 37° C. to 47° C. As long as the temperature is not (676) greater than 47° C., the process remains in the intermediate heating control stage (674). When (677) the temperature exceeds 47° C., the message “User Message: Cell has reached 47 degrees C. Cell will now heat to 55 degrees C. Please wait for red flashing light . . . ” is displayed (678).

According to the present invention, the method (600) and device (100) are designed so that the user can select from multiple chemical/liquid mixtures to be used for the crystal growth and essentially the same saturation temperature is used for whichever mixture is chosen. This simplifies the control process (600) since there is just one process and essentially a single temperature profile. This also allows the design of the mechanical aspects of the device (100) to be simplified and optimized for the single range of temperatures. The most sensitive and crucial period in the process of the present invention for producing large crystals is the cooling at the beginning of the growth of the crystal, which starts at the saturation temperature and proceeds downwards. Preferably, the saturation temperatures of all the chemical/liquid mixtures are with 3° C., more preferably 2° C., still more preferably 1° C., still more preferably 0.5° C., still more preferably 0.3° C., and still more preferably 0.1° C. The device of the present invention uses semi-active heating control, i.e., there is a heater but no active cooling. Cooling is due to the loss of heat to the environment. The construction of the device (100) is complex and so heat loss is a complicated function which may vary considerably with both the ambient and internal temperature. Factors to be considered for a theoretical modeling include the expansion and contraction of the various components and the resulting varying degrees of thermal contact between the components. Heat loss as a function of temperature can most easily be found empirically. With crystallization beginning at the same temperature for each chemical, as per the method of the present invention, optimization of the control processes which provide cooling by balancing heat loss to the environment with heating by the heating element (2060) is facilitated.

As described in more detail below, according to the present invention, the saturation temperature is chosen to be far enough above ambient temperature that enough of the chemical is dissolved to provide a large crystal, yet the peak temperature and saturation temperature are not so high that (i) a large uncertainty in the amount of dissolved chemical is produced, (ii) the slope of the saturation curve is so great that it is difficult to achieve sufficiently precise temperature control to grow the crystal without producing crystal nucleation in the liquid, and/or (iii) the temperatures provide a significant danger to the user. The power input (2012) to the cell (100) is a 12 Volt input which draws 30 Watts or less. Ambient temperature, i.e., room temperature, is generally around 21° C. The temperature at which proteins denature is about 60° C. (although extended exposure to temperatures as low as 48° C. can cause denaturing), so 60° C. is the temperature at which the heat of the device (100) and the contained solution (130) becomes significantly dangerous.

The process (600) now enters the final heating control stage (679), which is time region (730) in FIG. 7A, where the temperature is high enough that the chemical is completely dissolved. In the final heating control stage (679)/(730), the red LEDs (2041) are lit, indicating the temperature is hot enough to present some danger, the heating resistors (2060) are on, the motor (2020) of the agitator is turned on to the high level, and the temperature is monitored by the thermistor (2042). (It should be noted that the device (100) includes safety controls which insure that, even in a manual control mode, the heating resistors (2060) are not fully powered without the agitator motor (2020) being on at the high level, and if the chamber (100) is opened the agitator motor (2020) is turned off.) During this period (730) the temperature is monitored (680) as it rises from 47° C. to the peak temperature of 55° C., as shown in FIG. 7A. According to the preferred embodiment of the present invention, the temperature of the solution (130) is raised to a peak temperature high enough above the saturation temperature that no microcrystals, i.e., groups of a few or several molecules with crystalline bonding, remain in the solution (130). When microcrystals remain in the solution (130) the solution (130) will appear somewhat cloudy, and when no microcrystals remain, the solution (130) will appear clearer. According to the preferred embodiment of the present invention, the temperature of the solution (130) is raised to a peak temperature 3° C. to 15° C. higher than the saturation temperature, more preferably 5° C. to 10° C. higher than the saturation temperature, and still more preferably 7° C. to 8° C. higher than the saturation temperature. As long as the temperature is not (681) greater than 55° C., the process remains in the final heating control stage (679). With the 30 Watts or less of power drawn from the power input (2012), the heating stages (710), (720) and (730) may take up to six hours. When (682) the temperature exceeds 55° C., the message “User Message: Cell has reached 55 degrees C. Cell dissolved all chemicals. Cell will now cool to 49 degrees C. Please wait for green flashing lights . . . ” is displayed (683).

The process (600) now enters the initial cooling control stage (684), which is time region (740) in FIG. 7A. In the initial cooling control stage (684) the red LEDs (2041) are lit and blinking (the red color indicating a high temperature, and the blinking light indicating that a user action is required or will soon be required), the heating resistors (2060) are off, the motor (2020) of the agitator is on at the high level, and the temperature is monitored by the thermistor (2042). During this period (684)/(740), which lasts about 20 minutes, the temperature is monitored (690) as it falls from 55° C. to 49° C. Because the heating resistors (2060) are off, the temperature curve in this period (740) is concave upwards. As long as the temperature is not (691) less than 49° C., the process remains in the initial cooling control stage (684). When (692) the temperature drops below 49° C., the process (600) enters the temperature stasis stage (693).

In the temperature stasis stage (693), which is region (750) in FIG. 7A, the green LEDs (2041) are lit and blinking, the heating resistors (2060) are on, the motor (2020) of the agitator is on at a low level, and the temperature is monitored by the thermistor (2042). (According to an alternate preferred embodiment the agitator motor (2020) is turned off during the temperature stasis stage (693). And according to another alternate embodiment, the stasis temperature, rather than being above the saturation temperature, is slightly below the saturation temperature. In this case, if agitation is maintained and the solution (130) is in the supersaturated state and has not begun crystallization, the introduction of the seed crystal (237) and halting the agitation induces a dramatic, rapid crystallization on the seed crystal (237).) According to the preferred embodiment, when the agitation is at the low level the magnetic stirrer housing (2090) rotates at 20 to 30 rpm, and more preferably at 25 rpm. The thermistor (2042) measures the temperature every second, and a running average of the temperature over the last 30 seconds is maintained. When the 30-second running average shows a temperature drop of 0.1° C. or more below 49° C., the heating resistors (2060) are turned on to raise the temperature. During this period (750) the heating resistors (2060) are turned on whenever the thermistor (2042) detects the temperature has dropped below the stasis temperature of 49° C.

During the temperature stasis stage (693)/(750), the user message, “User Message: Cell has reached 49 degrees C. This is the seeding temperature. Open Cell top & unscrew plug. Attach seed to plug inside. Screw plug with seed back into Cell. Close Cell tightly.” is displayed (694). The user then removes the o-ring (255) from the end of the seed crystal chamber (253), inserts a seed crystal (237) into the chamber (253) of the seed crystal holder (250), replaces the o-ring (255) at the end of the seed crystal chamber (250), screws the threaded top (251) of the seed crystal holder (250) into the threaded well (234) at the bottom of the screw cap (235), and screws the screw cap (235) back into the tube interface (225). The seed crystal (237) may be a single crystal of the chemical or may be a tablet of the compressed powered chemical. When the user has inserted the seed crystal (237), the user indicates that the seed crystal (237) has been inserted by clicking on a “next” button (not shown).

Because the stasis temperature, 49° C., of this period (693)/(750) is greater than the saturation temperature, the seed crystal (237) will vanish if the user takes too long to proceed with the process (600). However, the seed crystal (237) is of a large enough size that the user has several minutes to insert the seed crystal (237) into the liquid (130) and reseal the chamber (220). (According to an alternate preferred embodiment, during this period (750) the stirrer housing (2090) is rotated at an extremely high level, i.e., in the neighborhood of 1000 rpm, so that a hollow is created at the center of the top of the liquid (130) by the resulting whirlpool. This gives the user more time to insert the seed crystal (237) and close the chamber (120) since the seed crystal (237) will not dissolve in the liquid (130) since it (237) is not touching the liquid (130).)

Then the user message, “User Question: Are you sure the Cell is well closed?” is displayed (6010). If the user answers “No” (6011) or if there is no response, then the user message, “User Message: Close Cell or abort experiment” is displayed (6013). If the user answers yes (6012), the user message, “User Message: The Cell will now grow the seed larger. This will take several hours/days. Please wait . . . ” is displayed (6015), and the apparatus (100) enters the crystal growing phase (760).

In the crystal growing phase (760) the crystal growth parameters (6016) are that the yellow LEDs (2041) are lit, the heating resistors (2060) are controlled as described below, the motor (2020) of the agitator is on at a low level, and the temperature is monitored by the thermistor (2042). The seed crystal (237) initially has a small surface area, so only a small amount of material can crystalize on the seed crystal (237) per unit time, and a rapid drop in temperature is to be avoided since it would produce crystal nucleation in the liquid (130). However, as the seed crystal (237) increases in size the amount which can be deposited on the seed crystal (237) increases, so the temperature can be decreased more rapidly without producing nucleation. According to the present invention, the temperature is controlled to drop off slowly at the beginning, increase to a maximum level, and then asymptote to room temperature, i.e., the temperature curve has an initial concave downwards portion (761), an intermediate, constant slope portion (762), and a subsequent concave upwards portion (763). According to the preferred embodiment of the present invention, monitoring of the temperature and controlled heating is applied to balance heat loss to the ambient environment so the temperature drops by 0.1° C. the first hour, 0.2° C. the second hour, 0.3° C. the third hour, 0.4° C. the fourth hour, and 0.5° C. the fifth hour and subsequent hours until the temperature becomes so close to the ambient temperature that a drop by 0.5° C. per hour is not possible since the apparatus does not include an active cooling mechanism.

Maintaining the agitation at the low level with the magnetic stirrer housing (2090) rotating at 20 to 30 rpm, and more preferably at 25 rpm, creates fluid flow within the liquid (130) which inhibits crystal nucleation until the temperature drops substantially below the saturation temperature. Within roughly 20 to 30 minutes, growth of the seed crystal (237) is visible. The entire crystal growing stage (760) takes between 12 and 72 hours and produces a crystal or crystal cluster of roughly 8 cm in diameter. It should be noted that any heating applied to slow the cooling due to ambient heat loss acts to also reduce the amount of crystal nucleation in the solution (130). It should be noted that any heating applied to slow the cooling due to ambient heat loss acts to also reduce the amount of crystal nucleation in the solution (130). Generally, the slower the crystal growth is induced, the clearer the crystal because less dislocations in the crystal structure result.

During the crystal growing stage (6016)/(760), the user has the option (not shown in FIGS. 6F and 6G) of halting the process (600) at any time by hitting the space bar of the computer keyboard that the device (100) is connected to via the USB port (2011). If the user decides he/she likes the crystal (150) at any point and halts the crystal growing process (6016)/(760), the agitator motor (2020) remains rotating at the low level, and the temperature is maintained at the current temperature, via monitoring by the thermistor (2042) and the application of heat by the heating resistors (2060) to balance the loss of heat to the ambient environment.

The temperature change is monitored (6020) at regular intervals as a function of time during the crystal growing stage (6016)/(760), and if the change in temperature is not (6021) less than 1° C. in 200 minutes, then the process (600) stays in the crystal growing phase (6016)/(760). However, when the change in temperature is (6022) less than 1° C. in 200 minutes, then the contents of the chamber (120) has reached a temperature close to the ambient temperature and semi-active cooling cannot be used to reduce the temperature substantially further to produce further crystal growth. The user message, “User Message: The Cell has completed the crystal growth” is then displayed (6024) until the user acknowledges by clicking (not shown) an acknowledgement button. Then the message, “User input: Are you satisfied with the result?” is displayed (6030). If the user replies that he/she is not (6031) satisfied, then the message, “User Input: Do you want to dissolve this crystal and restart the experiment with a new seed crystal?” is displayed (6035). If the user responds that he/she does (6037) wish to restart the experiment, then there is a return (6039) to the testing step (615) of the process (600). If the user responds that he/she does not (6036) wish to restart the experiment, then there is a return (6038) to the main menu (6000).

If, when the user is queried (6030) as to whether he/she is satisfied with the result, the user responds affirmatively (6032), then the LEDs (2041) are powered (6040), the user message, “User Message: You can now open the Cell's top screw plug and either remove the crystal carefully, or you can leave the crystal inside the Cell and use it as a night light and add some sparkles” is displayed (6045), and there is a return (6050) to the main menu (6000). According to an alternate embodiment of the present invention, the LEDs (2041) are synced to an audio data signal, as is well-known in the art musical/entertainment lighting, so the audio data signal causes flashing of the LEDs (2041).

A flowchart of the crystal growth method (1600) according to an alternate preferred embodiment of the present invention where a whirlpool (190) is created by the stirrer (2098) during initial stages of the process (1600) to prevent the solution (130) from contacting the seed crystal (237) is provided in FIGS. 6H, 6I, 6J, 6K, 6L, 6M, 6N and 6O, and FIG. 7B shows the corresponding temperature and lighting versus time and agitation level versus time. The software interface first displays (1605) the message, “User Input: Is the DC power adapter connected to the Krystal Cell?” If the user enters that it is not (1606) or does not reply, then the process (1600) returns to the display (1605) of “User Input: Is the DC power adapter connected to the Krystal Cell?” If the DC power adapter is (1607) connected to the apparatus via the power input socket (2012), then the software interface displays (1610) the message, “User Input: Is Cell Mini USB connected to the computer USB port?” If the user enters that it is not (1611) or does not reply, then the process (1600) returns to the display (1610) of “User Input: Is Cell Mini USB connected to the computer USB port?” If the apparatus (100) is (1612) connected to a computer (not shown) via the mini USB socket (2011), then the software interface displays (1615) the message, “User Message: Testing Cell—please wait a minute . . . ”. The cell is then tested (1617) by calling an error check routine, ERROR_CHECK, which checks an error check variable, ERROR_CHECKSUM$. The error check variable ERROR_CHECKSUM$ must have a value of seven if the process (1600) is to proceed. The value of ERROR_CHECKSUM$ is initialized with a value of zero, and the value of ERROR_CHECKSUM$ is incremented by unity if a USB cable is connected to the USB port (2011), the value of ERROR_CHECKSUM$ is incremented by unity if there is a signal from the microprocessor (2019) to the computer, the value of ERROR_CHECKSUM$ is incremented by unity if power consumption by the LEDs (2041) is confirmed, the value of ERROR_CHECKSUM$ is incremented by unity if power consumption by the motor (2020) is confirmed, the value of ERROR_CHECKSUM$ is incremented by unity if the thermistor (2042) senses a change in temperature due to heating by the heating resistors (2060), the value of ERROR_CHECKSUM$ is incremented by unity if the user has indicated that the chamber (220) is closed and sealed (or in an alternate embodiment, if contacts at the top of the chamber (220) indicate that the chamber (220) is closed and sealed). In an alternate preferred embodiment, the value of ERROR_CHECKSUM$ is further incremented by unity if the current through the solution resulting from the application of a known voltage indicates a resistance consistent with the presence of the allowed chemicals for use with the device (100) in the proper concentrations, e.g., pure water or an empty container will not provide the proper resistance. If ERROR_CHECKSUM$ does not (1621) have a value of seven, then the errors which cause the value of ERROR_CHECKSUM$ to be less than seven are displayed and the process (1600) returns to the main menu (6000). However, if ERROR_CHECKSUM$ does (1622) have a value of seven, then the message, “User Input: Please choose the crystal growing chemical. Options: MAP, ALUM or IMPORT” is displayed (625). The variable MAT$ is then defined to be either “MAP” (1626), “IMPORT” (1627) or “ALUM” (1628), depending on the input provided by the user.

The user message, “User instruction: Fill Cell with Chemical MAT$” is then displayed (1630), where MAT$ has been defined as MAP or ALUM or the material specified upon importing information. Then the user message, “User Input: Are you done?” is displayed (1635). If (1636) the user is not done or if the user enters “No,” then the process (1600) does not proceed. If (1637) the user enters “Yes,” then the user message, “User Message: Please fill Cell with water” is displayed (1638) until the user indicates (1639) that this has been performed (by clicking on a “next” button, or the like). Then the user message, “User Input: Is the Cell filled with enough water?” is displayed (1640). If (1641) the user answers “No” or there is no response from the user, the process (1600) does not proceed. However, if (1642) the user answers “Yes,” then the user message, “User Message: Load seed with seed” is displayed (1643).

The user loads the seed crystal (237) into the seed crystal chamber (253) and retains the seed crystal (237) within the chamber (253) by inserting the o-ring (255) into the end of the chamber (253), as described above. After the user hits a confirmation button (1644), the user message, “User message: Screw seeder into top lid” is displayed (1645). The user then screws the threaded top (251) of the seed holder (250) into the threaded well (234) of the cap (235). After the user hits a confirmation button (1646), the user message, “User message: Please close the Cell and screw it shut” is displayed (1648). The user then screws the cap (235) into the tube interface (225) and hits a confirmation button (not shown). Then the user message, “User Input: Is the Cell closed properly now?” is displayed (1650). If (1651) the user answers “No” or there is no response from the user, the process (1600) does not proceed. However, if (1652) the user answers “Yes,” a cell testing procedure, ERROR_CHECK, is called (1653). As before, ERROR_CHECKSUM$ must have a value of seven if the process (1600) is to proceed. If ERROR_CHECKSUM$ does not (1661) have a value of seven, then the errors which cause the value of ERROR_CHECKSUM$ to be less than seven are displayed and the process (1600) returns to the main menu (6000). However, if ERROR_CHECKSUM$ does (1662) have a value of seven, then the message, “User Message: Starting crystal growing sequence now. Cell is heating to 37 degrees C. Please wait . . . ” is displayed (1663).

The agitator motor (2020) is then turned on (1655) at the very high level, creating a vortex (190) at the top center of the chemical/liquid mixture (130). The chamber (253) of the seed holder (250) is located inside the vortex (190), as is shown in FIG. 1C, so the chemical/liquid mixture (130) does not make contact with the seed crystal (237). The process (1600) now enters preliminary heating control stage (1665), which is time region (1710) in FIG. 7B. In the preliminary heating control stage (1665) the blue LEDs (2041) are lit, the heating resistors (2060) are turned on, the motor (2020) of the agitator is on at the very high level, and the temperature is monitored by the thermistor (2042). The agitation during this period (1710), the period (1720) that follows where the temperature is raised to the saturation temperature, and the next period (1730) where the temperature is raised above the saturation temperature, increases the speed at which the chemical MAP$ is dissolved. During the initial period (1710) the temperature is monitored (1670) as it rises from the ambient temperature (which is typically in the neighborhood of 21° C.) to 37° C. As long as the temperature is not (1671) greater than 37° C., the process remains in the preliminary heating control stage (1710)/(1665).

When (1672) the temperature exceeds 37° C., the message “User Message: Cell has reached 37 degrees C. Cell will now heat to 47 degrees C. Please wait . . . ” is displayed (1673). The process (1600) now enters the intermediate heating control stage (1674), which is time region (1720) in FIG. 7B. In the intermediate heating control stage (1674)/(1720) the yellow LEDs (2041) are lit, the heating resistors (2060) are on, the motor (2020) of the agitator is on at the very high level, and the temperature is monitored by the thermistor (2042). During this period (1720) the temperature is monitored (1675) as it rises from 37° C. to 47° C. As long as the temperature is not (1676) greater than 47° C., the process remains in the intermediate heating control stage (1674). When (1677) the temperature exceeds 47° C., the message “User Message: Cell has reached 47 degrees C. Cell will now heat to 55 degrees C. Please wait for red flashing light . . . ” is displayed (1678).

As described above for the process (600) of FIGS. 6B, 6C, 6D, 6E, 6F, 6G, and 7A, according to the present invention the method (1600) and device (100) are designed so that the user can select from multiple chemical/liquid mixtures to be used for the crystal growth and essentially the same saturation temperature is used for whichever mixture is chosen. This simplifies the control process (1600) since there is just one process and essentially a single temperature profile. This also allows the design of the mechanical aspects of the device (100) to be simplified and optimized for the single range of temperatures. The most sensitive and crucial period in the process of the present invention for producing large crystals is the cooling at the beginning of the growth of the crystal, which starts at the saturation temperature and proceeds downwards. Preferably, the saturation temperatures of all the chemical/liquid mixtures are with 3° C., more preferably 2° C., still more preferably 1° C., still more preferably 0.5° C., still more preferably 0.3° C., and still more preferably 0.1° C. The device of the present invention uses semi-active heating control, i.e., there is a heater but no active cooling. Cooling is due to the loss of heat to the environment. The construction of the device (100) is complex and so heat loss is a complicated function which may vary considerably with both the ambient and internal temperature. Factors to be considered for a theoretical modeling include the expansion and contraction of the various components and the resulting varying degrees of thermal contact between the components. Heat loss as a function of temperature can most easily be found empirically. With crystallization beginning at the same temperature for each chemical, as per the method of the present invention, optimization of the control processes which provide cooling by balancing heat loss to the environment with heating by the heating element (2060) is facilitated. According to the present invention, the saturation temperature is chosen to be far enough above ambient temperature that enough of the chemical is dissolved to provide a large crystal, yet the peak temperature and saturation temperature are not so high that (i) a large uncertainty in the amount of dissolved chemical is produced, (ii) the slope of the saturation curve is so great that it is difficult to achieve sufficiently precise temperature control to grow the crystal without producing crystal nucleation in the liquid, and/or (iii) the temperatures provide a significant danger to the user.

The process (1600) now enters the final heating control stage (1679), which is time region (1730) in FIG. 7B, where the temperature is high enough that the chemical is completely dissolved. In the final heating control stage (1679)/(1730), the red LEDs (2041) are lit, indicating the temperature is hot enough to present some danger, the heating resistors (2060) are on, the motor (2020) of the agitator is on at the very high level, and the temperature is monitored by the thermistor (2042). (It should be noted that the device (100) includes safety controls which insure that, even in a manual control mode, the heating resistors (2060) are not fully powered without the agitator motor (2020) being on at least at the high level.) During this period (1730) the temperature is monitored (1680) as it rises from 47° C. to the peak temperature of 55° C., as shown in FIG. 7B. According to the preferred embodiment of the present invention, the temperature of the solution (130) is raised to a peak temperature high enough above the saturation temperature that no microcrystals, i.e., groups of a few or several molecules with crystalline bonding, remain in the solution (130). When microcrystals remain in the solution (130) the solution (130) will appear somewhat cloudy, and when no microcrystals remain, the solution (130) will appear clearer. According to the preferred embodiment of the present invention, the temperature of the solution (130) is raised to a peak temperature 3° C. to 15° C. higher than the saturation temperature, more preferably 5° C. to 10° C. higher than the saturation temperature, and still more preferably 7° C. to 8° C. higher than the saturation temperature. As long as the temperature is not (1681) greater than 55° C., the process remains in the final heating control stage (1679). With the 30 Watts or less of power drawn from the 12 volt power input (2012), the heating stages (1710), (1720) and (1730) may take up to six hours. When (1682) the temperature exceeds 55° C., the message “User Message: Cell has reached 55 degrees C. Cell dissolved all chemicals. Cell will now cool to 49 degrees C. Please wait for green flashing lights . . . ” is displayed (1683).

The process (1600) now enters the initial cooling control stage (1684), which is time region (1740) in FIG. 7B. In the initial cooling control stage (1684) the red LEDs (2041) are lit and blinking (the red color indicating a high temperature, and the blinking light indicating that a user action is required or will soon be required), the heating resistors (2060) are off, the motor (2020) of the agitator is on at the very high level, and the temperature is monitored by the thermistor (2042). During this period (1684)/(1740), which lasts about 20 minutes, the temperature is monitored (1690) as it falls from 55° C. to 49° C. Because the heating resistors (2060) are off, the temperature curve in this period (740) is concave upwards. As long as the temperature is not (1691) less than 49° C., the process remains in the initial cooling control stage (1684). When (1692) the temperature drops below 49° C., the process (1600) enters the crystal growing phase (1760).

At the beginning of the crystal growing phase (1760), the user message, “User Message: The Cell will now grow the seed larger. This will take several hours/days. Please wait . . . ” is displayed (8015). In the crystal growing phase (1760) the crystal growth parameters (8016) are that the yellow LEDs (2041) are lit, the heating resistors (2060) are controlled as described below, the motor (2020) of the agitator is on at a low level, and the temperature is monitored by the thermistor (2042). When the agitator level goes from very high to low, the vortex (190) collapses and the solution (130) comes into contact with the seed crystal (237) in the seed crystal chamber (253).

The seed crystal (237) initially has a small surface area, so only a small amount of material can crystalize on the seed crystal (237) per unit time, and a rapid drop in temperature is to be avoided since it would produce crystal nucleation in the liquid (130). However, as the seed crystal (237) increases in size the amount which can be deposited on the seed crystal (237) increases, so the temperature can be decreased more rapidly without producing nucleation. According to the present invention, the temperature is controlled to drop off slowly at the beginning, increase to a maximum level, and then asymptote to room temperature, i.e., the temperature curve has an initial concave downwards portion (1761), an intermediate, constant slope portion (1762), and a subsequent concave upwards portion (1763). According to the preferred embodiment of the present invention, monitoring of the temperature and controlled heating is applied to balance heat loss to the ambient environment so the temperature drops by 0.1° C. the first hour, 0.2° C. the second hour, 0.3° C. the third hour, 0.4° C. the fourth hour, and 0.5° C. the fifth hour and subsequent hours until the temperature becomes so close to the ambient temperature that a drop by 0.5° C. per hour is not possible since the apparatus does not include an active cooling mechanism.

Maintaining the agitation at the low level with the magnetic stirrer housing (2090) rotating at 20 to 30 rpm, and more preferably at 25 rpm, creates fluid flow within the liquid (130) which inhibits crystal nucleation until the temperature drops substantially below the saturation temperature. Within roughly 20 to 30 minutes, growth of the seed crystal (237) is visible. The entire crystal growing stage (1760) takes between 12 and 72 hours and produces a crystal or crystal cluster of roughly 8 cm in diameter. Generally, the slower the crystal growth is induced, the clearer the crystal because less dislocations in the crystal structure result.

During the crystal growing stage (8016)/(1760), the user has the option (not shown in FIGS. 6F and 6G) of halting the process (1600) at any time by hitting the space bar of the computer keyboard that the device (100) is connected to via the USB port (2011). If the user decides he/she likes the crystal (150) at any point and halts the crystal growing process (8016)/(1760), the agitator motor (2020) remains rotating at the low level, and the temperature is maintained at the current temperature, via monitoring by the thermistor (2042) and the application of heat by the heating resistors (2060) to balance the loss of heat to the ambient environment.

The temperature change is monitored (8020) at regular intervals as a function of time during the crystal growing stage (8016)/(1760), and if the change in temperature is not (8021) less than 1° C. in 200 minutes, then the process (1600) stays in the crystal growing phase (8016)/(1760). However, when the change in temperature is (8022) less than 1° C. in 200 minutes, then the contents of the chamber (120) has reached a temperature close to the ambient temperature and semi-active cooling cannot be used to reduce the temperature substantially further to produce further crystal growth. The user message, “User Message: The Cell has completed the crystal growth” is then displayed (8024) until the user acknowledges by clicking (not shown) an acknowledgement button. Then the message, “User input: Are you satisfied with the result?” is displayed (8030). If the user replies that he/she is not (8031) satisfied, then the message, “User Input: Do you want to dissolve this crystal and restart the experiment with a new seed crystal?” is displayed (8035). If the user responds that he/she does (8037) wish to restart the experiment, then there is a return (8039) to the testing step (1615) of the process (1600). If the user responds that he/she does not (8036) wish to restart the experiment, then there is a return (8038) to the main menu (6000).

If, when the user is queried (8030) as to whether he/she is satisfied with the result, the user responds affirmatively (8032), then the LEDs (2041) are powered (8040), the user message, “User Message: You can now open the Cell's top screw plug and either remove the crystal carefully, or you can leave the crystal inside the Cell and use it as a night light and add some sparkles” is displayed (8045), and there is a return (8050) to the main menu (6000). According to an alternate embodiment of the present invention, the LEDs (2041) are synced to an audio data signal, as is well-known in the art musical/entertainment lighting, so the audio data signal causes flashing of the LEDs (2041).

The solubility curve (900) for ammonium phosphate monobasic (MAP) in water is shown in FIG. 9A. The solubility Sin grams per 100 grams of water versus temperature T in degrees Celsius is concave upwards and is approximated by the polynomial

S=7×10⁻⁵T³+0.0008T²+0.6915T+22.554. (eq. 1)

At slightly above freezing, i.e., 0° C., about 22.5 grams of MAP is soluble in 100 grams of water, at 21° C. about 40 grams of MAP is soluble in 100 grams of water, at 47.5° C. about 65 grams of MAP is soluble in 100 grams of water, and near the boiling temperature of water, i.e., 100° C., about 170 grams of MAP is soluble in 100 grams of water. (It should be noted that the polynomial of the above equation is an approximation to the solubility curve and experimentally it is found that roughly 174 grams of MAP is soluble in 100 grams of water. In general, there will always be differences between an experimentally derived solubility curve and a functional approximation to data points from the solubility curve.)

The solubility curve (950) for potassium aluminum sulfate, or alum, in water is shown in FIG. 9B. The solubility Sin grams per 100 grams of water versus temperature Tin degrees Celsius is concave upwards and is approximated by the polynomial

S=0.0002T³−0.0097T²+0.5587T+4.9514. (eq. 2)

At slightly above freezing, i.e., 0° C., about 5 grams of alum is soluble in 100 grams of water, at 21° C. about 15 grams of alum is soluble in 100 grams of water, at 47.5° C. about 31 grams of alum is soluble in 100 grams of water, and near the boiling temperature of water, i.e., 100° C., about 163 grams of alum is soluble in 100 grams of water. (It should be noted that although the graph shows data to 80° C. and the melting temperature of alum is 92° C.—at which point the issue becomes liquid-liquid “miscibility” rather than liquid-solid “solubility”—the curve of FIG. 9B is a reasonable approximation of the amount of alum dissolved in water up to 100° C.)

Larger crystals can be grown by increasing the amount of the chemical dissolved in the liquid. This is accomplished by increasing the amount of the chemical added to the liquid and increasing the temperature to which the mixture is heated as per the solubility curves (900) and (950) of FIGS. 9A and 9B, respectively. However, because the solubility curves (900) and (950) are concave upwards, not only does the amount of chemical soluble in water increase increasingly rapidly with temperature, an uncertainty or error in temperature control or measurement produces an increasingly large difference in the amount of chemical which can be dissolved because of the increasing slope of the solubility curves (900) and (950). More particularly, for a solubility curve of the form

S=aT³+bT²+cT+d, (eq. 3)

i.e., a cubic polynomial, the relationship between the uncertainty ΔS in solubility and the uncertainty ΔT in temperature is

ΔS=ΔT(3aT²+2bT+c). (eq. 4)

Therefore, for low temperatures, ΔS≈c≈T, i.e., the uncertainty ΔS in solubility is linearly related to the uncertainty ΔT in temperature. However, for high temperatures, ΔS≈3 a T² ΔT, i.e., the uncertainty ΔS in solubility increases as the square of temperature T.

To avoid nucleation in the solution (130) during the crystal growth stage (6016)/(760), the temperature drop per unit time, dT/dt, must be slow enough to allow the amount of chemical coming out of solution to add to the crystal seed (237). For a drop in temperature δT in a solution of volume V, the amount of chemical which comes out of solution is V(dS/dT) δT. The rate that the chemical can form as crystal on the crystal seed (237) is proportional to the density of chemical molecules in the solution, i.e., S, and the surface area of the crystal seed (237), i.e., 4 π R², where R is the characteristic radius of the crystal seed (237) at whatever stage of its growth it is at. So to avoid crystal nucleation in the solution (130),

dS/dT*dT/dt˜f(T)S R², (eq. 5)

where f(T) is a function of the temperature which reflects the kinetics of the molecular bonding in crystal formation. This shows that a smaller decline in temperature per unit time, dT/dt, is required if the slope of the solubility curve, dS/dT, is large. Furthermore, as the crystal increases in size, i.e., as the characteristic radius R increases, the decline in temperature per unit time, dT/dt, may be increased.

Rather than attempting to maximize the amount of chemical dissolved in the liquid by having a high saturation temperature, according to the present invention less taxing demands are placed on the temperature control, which means less taxing demands are placed on: the temperature monitoring provided by the thermistor (2042), the control of the heating produced by heating resistors (2060), the software control provided by the microprocessor (2015), and the knowledge/understanding of the heat insulation provided by the crystal growth cell (100). According to the present invention, an amount of chemical is used which is large enough to produce a large crystal, but produces a saturation temperature at which the slope dS/dT of the solubility curve is not too large. The slope of the solubility curves (900) and (950) is least at the freezing temperature, 0° C., of water and greatest at the boiling temperature, 100° C., and that is generally the case for most solids soluble in a liquid. According to the preferred embodiment of the present invention, the saturation temperature Tₛ is chosen to be at a temperature where the slope of the solubility curve is less than the average of the slope of the solubility curve at the freezing temperature T_{f} and the slope of the solubility curve at the boiling temperature T_{b}, i.e.,

$$c \frac{d S}{d T} {\vert}_{T = {T}_{S}} < \frac{1}{2} [ \frac{d S}{d T} {\vert}_{T = {T}_{f}} + \frac{d S}{d T} {\vert}_{T = {T}_{b}} ] , \qquad ( eq . 6 )$$

where c=1. More preferably c=0.75, still more preferably c=0.5, still more preferably c=0.3, and still more preferably c=0.2.

FIG. 9C shows a solubility curve (970) where the curve (970) is concave upwards in a low temperature region (981) and concave downwards in a high temperature region (982). The maximum slope, (dS/dT)ₘₐₓ, occurs at the inflection point (975). For chemical solutions for which the solubility curve is not concave upwards at higher temperatures, according to the preferred embodiment of the present invention the saturation temperature Tₛ is chosen to be at a temperature where the slope dS/dT of the solubility curve is less than the average of the slope dS/dT of the solubility curve at the freezing temperature T_{f} and the maximum slope (dS/dT)ₘₐₓ of the solubility curve between the freezing temperature T_{f} and the boiling temperature T_{b}, i.e.,

$$c \frac{d S}{d T} {\vert}_{T = {T}_{S}} < \frac{1}{2} [ \frac{d S}{d T} {\vert}_{T = {T}_{f}} + \frac{d S}{d T} {\vert}_{max} ] , \qquad ( eq . 7 )$$

where c=1. More preferably c=0.75, still more preferably c=0.5, still more preferably c=0.3, and still more preferably c=0.2.

However, because large crystals are desired, the saturation temperature Tₛ for the liquid/chemical mixture should not be too close to the freezing temperature T_{f} so a substantial amount of the chemical is dissolved. According to the present invention the saturation temperature Tₛ is chosen to be high enough that terms of higher order than linear in the solubility curve (900)/(950) begin to contribute so the slope at the saturation temperature Tₛ is somewhat greater than that at the freezing temperature T_{f}. More specifically, according to the present invention

$$k \frac{d S}{d T} {\vert}_{T = {T}_{f}} = \frac{d S}{d T} {\vert}_{T = {T}_{S}} , \qquad ( eq . 8 )$$

where preferably 1.25≦k≦2.5, more preferably 1.5≦k≦2.0, more preferably 1.65≦k≦1.85, still more preferably 1.7≦k≦1.8, and still more preferably k≈1.75.

As mentioned above in the description of the process (600) of the preferred embodiment of the present invention and shown in the temperature profiles (700) and (1700) of FIGS. 7A and 7B, for whichever chemical is used, the amount of the chemical added to the water produces a saturation temperature of 47.5° C. According to the preferred embodiment, for MAP, 332 grams of the chemical is used with 513 grams of water; for alum, 194 grams of the chemical is used with 624 grams of water. For MAP, the slope dS/dT of the solubility curve at 0° C. is roughly 0.69 (all slopes discussed with reference to solubility curves have units of inverse degrees Celsius), the slope dS/dT at 100° C. is 2.95, and the slope at 47.5° C. is 1.24—so the slope dS/dT at the saturation temperature Ts is indeed (i) roughly 80% greater than the slope dS/dT at the freezing temperature T_{f} and (ii) less than the average of the slopes at the boiling and freezing points, which is 1.84. For alum, the slope dS/dT at 0° C. is roughly 0.56, the slope dS/dT at 100° C. is 4.62, and the slope dS/dT at 47.5° C. is 0.99—so the slope dS/dT at the saturation temperature Ts is indeed (i) roughly 77% greater than the slope dS/dT at the freezing temperature T_{f} and (ii) less than the average of the slopes at the boiling and freezing points, which is 2.59.

Thus, it will be seen that the improvements presented herein are consistent with the objects of the invention for a method and apparatus for crystal growing. While the above description contains many specificities, these should not be construed as limitations on the scope of the invention, but rather as exemplifications of preferred embodiments thereof. Many other variations are also within the scope of the present invention. For example: aspects of the cell may have various other different constructions—for instance, the cap and base may be a single integrally-formed piece, other motors may be used, etc.; the device may not include a seed crystal holder; the components may be situated differently—for instance, the stirrer may be at the top of the chamber; other chemicals may be used; only a single chemical may be used; the crystals may be grown in a liquid other than water; a single large crystal rather than a crystal cluster may be grown; active cooling may be used; the chamber may have better insulation, such as a double-walled construction possibly enclosing a vacuum; the chamber may have a sensor to sense when the chamber is properly sealed; the device may not include an agitator; agitation may not begin until the crystal formation stage; the chamber tube may be coated with an infra-red heating foil to provide heating for the chamber; electrical contacts to the liquid, which may for instance be the thermistor cap and the heating element, may be used to monitor the conductivity of the liquid to insure that the correct liquid and/or the correct chemicals and/or the correct ratios are utilized; the components may be made of other materials—for instance, the heating element may be glass or stainless steel or a Teflon-coated material, plastics other than polycarbonate plastic may be used, materials other than anodized aluminum, such as stainless steel, may be used, etc.; active cooling may be used, for instance via the Peltier thermoelectric effect; the method and apparatus may be adapted for other uses, such as tissue growth or acrylics production; the apparatus may be used with gases or gels; pressure may be manipulated to induce transformations such as dissolving and crystallization; the seed crystal can be encapsulated in a gel or some other dissolvable material to give the user more time to insert the seed crystal in the liquid, and allow more flexibility in the temperature control and greater repeatability; the seed crystal may be inserted into the liquid using a mechanism, possibly an automated mechanism, that would circumvent the need to open the container; the seed crystal may be located at the bottom of the chamber; the seed crystal may be attached to the seed crystal holder in another fashion, such as gluing; the system may be powered solely by power from the USB input; a different saturation temperature may be used; heating may not be applied to hold the temperature constant during the stage when the seed crystal is inserted into the solution; the cooling curve for crystal growth may be different—for instance, a constant rate of cooling, such as 0.5° C. per hour, may be used; no heat may be applied during the crystal growth stage; no agitation may be used during any or all of the process stages; different rates of agitation may be used during any or all of the process stages; the temperature curve during the crystal growth stage may have a different shape—for instance, there may not be a constant slope portion; other variables may be included or variables may be excluded from the error check; etc.

Furthermore, the description of the physical principles underlying the operation and performance of the present invention are described as presently understood, but may include approximations, simplifications and assumptions and are not intended to be limiting. For example: a solubility curve may be approximated by a different function, such as a polynomial of a higher or lower degree; least squares or other fits may be used to find a functional approximation to the solubility curve; the solubility curve may differ from the functional approximation to the solubility curve, and the difference may be greater at the high temperature end, the low temperature end, or in an intermediate region; a solubility curve may have portions which are not concave upwards; agitation of the mixture may have effects other than those described or contrary to or counteracting those described; the heating or semi-active cooling may be different from that shown during any of the heating or cooling stages, including the crystal growth stage; the pH may be altered to affect the solubility; crystal growth may have a different dependence on temperature, time, or the solubility curve; etc.

Accordingly, it is intended that the scope of the invention be determined not by the embodiments illustrated or the physical analyses motivating the illustrated embodiments, but rather by the appended claims and their legal equivalents.

1. A method for growing a crystal from a solution of a chemical in a container, comprising the steps of:
adding said chemical and a liquid in a relative amount to said container to provide a mixture, said chemical having a solubility curve of maximum dissolved amount of said chemical relative to amount of said liquid versus temperature, said relative amount of said chemical in said liquid providing a saturation temperature below a boiling point of said liquid,
heating said mixture to said saturation temperature to produce said solution of said chemical in said liquid,
submerging a seed crystal in said solution,
closing said container with said seed crystal in said solution to provide a closed cell system, and
controlling cooling of said solution by monitoring a current bulk temperature of said closed cell system and applying heating based on said current bulk temperature to balance ambient heat loss to a room-temperature ambient environment in direct thermal contact with said container of said solution to produce crystal growth on said seed crystal.

2. The method of claim 1 wherein said solubility curve has a maximum slope between said freezing point and a boiling point of said liquid, said saturation point slope being less than an average of said first slope and said maximum slope.

3. The method of claim 1 wherein said solubility curve has a maximum slope between said freezing point and a boiling point of said liquid, said saturation point slope being less than 0.75 times an average of said first slope and said maximum slope.

4. The method of claim 1 wherein said solubility curve has a maximum slope between said freezing point and said boiling point of said liquid, said saturation point slope being less than 0.5 times an average of said first slope and said maximum slope.

5. The method of claim 1 wherein said solubility curve has a first slope at a freezing point of said liquid, and said relative amount of said chemical in said liquid providing a saturation temperature at which said solubility curve has a second slope which is k times said first slope, where 1.25<k<2.5.

6. The method of claim 1 wherein said solubility curve has a first slope at a freezing point of said liquid, and said relative amount of said chemical in said liquid providing a saturation temperature at which said solubility curve has a second slope which is k times said first slope, where 1.5<k<2.0.

7. The method of claim 1 wherein said solubility curve has a first slope at a freezing point of said liquid, and said relative amount of said chemical in said liquid providing a saturation temperature at which said solubility curve has a second slope which is k times said first slope, where 1.65<k<1.85.

8. The method of claim 1 wherein said controlled cooling provides a temperature curve of descending temperature versus time which is concave downwards near said saturation temperature.

9. The method of claim 8 wherein said concave downwards portion of said temperature curve is within 5° C. of said saturation temperature.

10. The method of claim 8 wherein said concave downwards portion of said temperature curve is within 2° C. of said saturation temperature.

11. The method of claim 1 wherein said submerging of said seed crystal in said solution is performed while said solution has a temperature of said saturation temperature.

12. The method of claim 1 further including the step of heating said solution from said saturation temperature to a peak temperature above said saturation temperature where microcrystals are dissolved in said solution.

13. The method of claim 1 further including the step of modifying said controlled cooling by modifying said applying of said heating.

14. The method of claim 1 wherein said controlled cooling can be halted so said current bulk temperature is in stasis at a stasis temperature above said ambient temperature and growth of said crystal is immediately halted.

15. The method of claim 1 wherein said seed crystal is a tablet of compressed powder of said chemical.

16. The method of claim 1 further including the step, subsequent to said adding said chemical and said liquid to said container, of confirming sealing of said container, before allowing said heating of said mixture.

17. The method of claim 1 further including the step, subsequent to said adding said chemical and said liquid to said container, of checking said adding said chemical and said liquid to said container by checking the conductivity of said mixture, before allowing said heating of said mixture, said heating of said mixture being produced by a heating element which also acts as an electrical contact for said checking of the conductivity.

18. The method of claim 1 wherein said liquid is water.

19. The method of claim 1 wherein said mixture is illuminated in a first manner during a first stage of said method, and said solution is illuminated in a second manner a second stage of said method.

20. The method of claim 1 wherein said saturation temperature is below a protein denaturing temperature of 60° C.

21. A method for growing a crystal from a solution in a container, comprising the steps of:
selecting a selected chemical from a first chemical and a second chemical, said first chemical in a first relative amount in a liquid providing a said saturation temperature which is a lowest temperature at which said first chemical is completely dissolved in said liquid, and said second chemical in a second relative amount in said liquid providing said saturation temperature which is said lowest temperature at which said second chemical is completely dissolved in said liquid
mixing said selected chemical and said liquid to provide a mixture having said first saturation temperature,
heating said mixture to said saturation temperature to provide said solution,
submerging a seed crystal of said selected chemical in said solution, and
cooling of said solution to produce crystal growth on said seed crystal.

22. The method of claim 21 wherein said selected chemical in said liquid has a solubility curve which has a first slope at a freezing point of said liquid and a maximum slope between said freezing point and a boiling point of said liquid, said solubility curve having a third slope at said saturation temperature which is less than an average of said first and said maximum slope.

23. The method of claim 21 wherein said selected chemical in said liquid has a solubility curve which has a first slope at a freezing point of said liquid, and said solubility curve having a second slope at said saturation temperature which is k times said first slope, where 1.25<k<2.5.

24. The method of claim 21 wherein said controlled cooling provides a temperature curve of descending temperature versus time which is concave downwards near said saturation temperature.

25. The method of claim 21 wherein said submerging of said seed crystal in said solution is performed while said solution has a temperature of said saturation temperature.

26. The method of claim 21 wherein said mixture is agitated to produce a vortex at the top surface of said mixture, situating said seed crystal in said vortex, and altering the agitation so as to allow said vortex to collapse and submerge said seed crystal.

27. The method of claim 21 further comprising the step of heating said solution from said saturation temperature to a peak temperature above said saturation temperature where microcrystals are dissolved in said solution.

28. The method of claim 21 wherein said mixture is lighted in a first manner during said heating of said mixture, and said solution is lighted in a second manner during said controlled cooling of said solution.

29. The method of claim 21 further including the step of lighting in a first manner when said current temperature is in a first range and lighting in a second manner when said current temperature is in a second range.

30. The method of claim 21 further including the step of modifying said controlled cooling by modifying said applying of said heating.

31. The method of claim 21 wherein said controlled cooling can be halted so said current bulk temperature is in stasis at a stasis temperature above said ambient temperature and growth of said crystal is immediately halted.

32. The method of claim 21 wherein said seed crystal is a tablet of compressed powder of said chemical.

33. The method of claim 21 further including the step, subsequent to said adding said chemical and said liquid to said container, of confirming sealing of said container, before allowing said heating of said mixture.

34. The method of claim 21 further including the step, subsequent to said adding said chemical and said liquid to said container, of checking said adding said chemical and said liquid to said container by checking the conductivity of said mixture, before allowing said heating of said mixture.

35. A method for growing a crystal from a solution of a chemical in a container, comprising the steps of:
adding said chemical and a liquid in a relative amount to said container to provide a mixture, said chemical having a solubility curve of maximum dissolved amount of said chemical relative to amount of said liquid versus temperature, said relative amount of said chemical in said liquid providing a saturation temperature below a boiling point of said liquid, said solubility curve having a first slope at a freezing point of said liquid and a second slope at a boiling point of said liquid, and said solubility curve having a saturation point slope at said saturation temperature which is less than 0.75 times an average of said first slope and a maximum slope of said solubility curve between said freezing point and a boiling point of said liquid;
heating said mixture to said saturation temperature to produce said solution of said chemical in said liquid;
submerging a seed crystal in said solution;
closing said container with said seed crystal in said solution to provide a closed cell system; and
controlled cooling of said solution by monitoring a current bulk temperature of said closed cell system and applying heating based on said current bulk temperature to balance ambient heat loss to a room-temperature ambient environment in direct thermal contact with said container of said solution to produce crystal growth on said seed.

36. A method for growing a crystal from a solution of a chemical in a container, comprising the steps of:
adding said chemical and a liquid in a relative amount to said container to provide a mixture, said chemical having a solubility curve of maximum dissolved amount of said chemical relative to amount of said liquid versus temperature, said relative amount of said chemical in said liquid providing a saturation temperature below a boiling point of said liquid,
heating said mixture to said saturation temperature to produce said solution of said chemical in said liquid,
agitating said solution to produce a vortex at the top surface of said solution,
situating a seed crystal in said vortex,
altering the agitation so as to allow said vortex to collapse and submerge said seed crystal,
cooling said solution to produce crystal growth on said seed crystal.

37. The method of claim 36 wherein said cooling is a controlled cooling of said solution by monitoring a current bulk temperature of said solution and applying heating based on said current temperature to balance ambient heat loss to a room-temperature ambient environment in direct thermal contact with said container of said solution to produce crystal growth on said seed crystal.

38. The method of claim 37 wherein said allowing of said vortex to collapse occurs after said mixture has been heated to said saturation temperature.

39. A method for growing a crystal from a solution of a chemical in a container, comprising the steps of:
adding said chemical and a liquid in a relative amount to said container to provide a mixture, said chemical having a solubility curve of maximum dissolved amount of said chemical relative to amount of said liquid versus temperature, said relative amount of said chemical in said liquid providing a saturation temperature below a boiling point of said liquid,
heating said mixture to said saturation temperature to produce said solution of said chemical in said liquid,
submerging a seed crystal in said solution, and
cooling of said solution by monitoring a current bulk temperature of said solution to produce crystal growth on said seed crystal, wherein said mixture is lighted in a first manner during said heating of said mixture, and said solution is lighted in a second manner during said cooling of said solution.

40. A method for growing a crystal from a solution of a chemical in a container, comprising the steps of:
adding said chemical and a liquid in a relative amount to said container to provide a mixture, said chemical having a solubility curve of maximum dissolved amount of said chemical relative to amount of said liquid versus temperature, said relative amount of said chemical in said liquid providing a saturation temperature below a boiling point of said liquid,
heating said mixture to said saturation temperature to produce said solution of said chemical in said liquid,
submerging a seed crystal in said solution, and
cooling of said solution by monitoring a current bulk temperature of said solution to produce crystal growth on said seed crystal, and lighting contents of said container in a first manner when said current bulk temperature is in a first range and lighting contents of said container in a second manner when said current temperature is in a second range.
